SEQUENCE LISTING (6 sequences)

SEQ ID NO: 1 - DNA, 29 bp, synthetic construct
  source 1..29: mol_type = other DNA
  modified_base 23: mod_base = OTHER; note = n is a deoxyuridine
aatgatacggcgaccaccgaganctacac

SEQ ID NO: 2 - DNA, 24 bp, synthetic construct
  source 1..24: mol_type = other DNA
caagcagaagacggcatacgagat

SEQ ID NO: 3 - DNA, 20 bp, synthetic construct
  source 1..20: mol_type = other DNA
aatgatacggcgaccaccga

SEQ ID NO: 4 - DNA, 21 bp, synthetic construct
  source 1..21: mol_type = other DNA
caagcagaagacggcatacga

SEQ ID NO: 5 - DNA, 29 bp, synthetic construct
  source 1..29: mol_type = other DNA
  modified_base 23: mod_base = OTHER; note = t is a 5 prime-vinyl thymidine
aatgatacggcgaccaccgagatctacac

SEQ ID NO: 6 - DNA, 24 bp, synthetic construct
  source 1..24: mol_type = other DNA
  modified_base 1: mod_base = OTHER; note = comprises a 5 prime-tridiol
caagcagaagacggcatacgagat

(19) United States
(12) Patent Application Publication
(10) Pub. No.: US 2024/0219835 A1
(43) Pub. Date: Jul. 4, 2024

(54) ETCH-FREE PHOTORESIST PATTERNING IN MULTI-DEPTH NANOWELLS

(71) Applicant: Illumina, Inc., San Diego, CA (US)

(72) Inventors: Tanmay Ghonge, San Diego, CA (US); David Prescott, San Diego, CA (US); Daniel Wright, San Diego, CA (US); Yekaterina Rokhlenko, San Diego, CA (US); Alexandra Szemjonov, Cambridge (GB); Francesca Patel-Burrows, Cambridge (GB); Gavriela Moskowitz, San Diego, CA (US)

(21) Appl. No.: 18/530,025

(22) Filed: Dec. 5, 2023

Related U.S. Application Data
(60) Provisional application No. 63/386,478, filed on Dec. 7, 2022.

(51) Int. Cl. G03F 7/11; B01J 19/00; B01L 3/00; G03F 7/038

(52) U.S. Cl. CPC G03F 7/11; B01J 19/0046; B01L 3/502707; G03F 7/038; B01J 2219/00722; B01L 2200/12

(57) ABSTRACT

Examples of flow cells include substrates. Embodiments of the present disclosure also relate to methods of fabricating flow cell substrates. Some example workflows exploit light blocking properties of an imprint layer such that the process does not include etch steps. Such processes may be used to create substrates compatible with simultaneous paired-end sequencing methods.

### CROSS-REFERENCE TO RELATED APPLICATIONS

The present application claims the benefit of priority to U.S. Provisional Application No. 63/386,478, filed Dec. 7, 2022, the content of which is incorporated by reference in its entirety.

### FIELD

The present application relates to the fields of nanopatterning processes and substrates comprising microscale or nanoscale patterned surfaces.

### REFERENCE TO SEQUENCE LISTING

The present application is being filed along with a Sequence Listing in electronic format. The Sequence Listing is entitled Sequence_Listing_ILLINC750A.xml created on Dec. 4, 2023, which is 8042 bytes in size. The information in the electronic format of the Sequence Listing is incorporated herein by reference in its entirety.

### BACKGROUND

Flow cells are devices that allow fluid flow through channels or wells within a substrate. Patterned flow cells that are useful in nucleic acid analysis methods include discrete wells having an active surface within inert interstitial regions. Flowcells fabricated through nanoimprint lithography (NIL) consist of a patterned crosslinked resin material on a glass substrate. Patterning is achieved by depositing a NIL resin containing polymerizable multifunctional monomers onto a glass substrate to create a thin film. A working stamp (WS) is pressed onto the resin surface and the NIL resin material deforms to fill the WS pattern. While the WS is still in contact with the surface, polymerization of the resin is initiated by exposure to light or heat, and the resin is cured. After the resin is sufficiently crosslinked such that it is no longer able to flow, the working stamp is peeled away from the surface, leaving behind an imprinted resin surface. The resulting nanostructured surface is then functionalized via multiple chemistry steps (e.g., silanization, hydrogel deposition, DNA oligo grafting) to support sequencing.

To ensure that DNA sequencing is spatially restricted into nanowells pre-defined by the working stamp pattern, the nanopatterned surfaces can be polished prior to the grafting of the DNA oligos.

Some available platforms for sequencing nucleic acids utilize a sequencing-by-synthesis approach (SBS). With this approach, nascent strands are synthesized, and the incorporation of labeled nucleotides to the growing strands are detected optically and/or electronically. Because template strands direct synthesis of the nascent strands, the sequence of the template DNAs may be determined from the sequential incorporated nucleotides that were added to the growing strand during SBS. In some examples, paired-end sequencing may be used, where forward strands are sequenced (read 1) and removed, and then reverse strands are constructed and sequenced (read 2). Simultaneous paired-end reading (SPEAR) method has been reported in U.S. Publication No. 2021/0024991 which is incorporated by reference in its entirety. The SPEAR method can simultaneously sequence the forward (read 1) and reverse (read 2) DNA strands, thus reducing sequencing time in half. The spatial separation of read 1 and read 2 pads is generally required in complicated multiple nanopatterning steps involving several layers of materials, some of which act as temporary sacrificial masks. Such a nanopatterning process may include one or more etch steps, for example to prepare the surface of the NIL resin for addition of a photoresist or to remove an aluminum layer prior to addition of a hydrogel layer.

As such, there remains a demand to develop new cost-effective processes to simplify the substrate patterning processes. Provided herein are new process of manufacturing patterned substrate without an etch step to support nucleic acid sequencing applications.

### SUMMARY

One aspect of the present disclosure relates to a patterned substrate, comprising:
a base support;
an imprint layer positioned over the base support, the imprint layer comprising a plurality of multi-level depressions, each depression comprising a deep portion having a first surface, and a shallow portion having a second surface, the deep portion and the shallow portion are defined by a step portion, wherein distance between the first surface and the base support corresponds to a first thickness of the imprint layer, the distance between the second surface and the base support corresponds to a second thickness of the imprint layer, and the second thickness is greater than the first thickness;
wherein the first thickness of the imprint layer is configured to allow sufficient passage of light to the deep portion of the depression to crosslink a photoresist, and the second thickness of the imprint layer is configured to sufficiently block passage of light to the shallow portion of the depression to inhibit crosslinking of the photoresist.

In some embodiments of the patterned substrate described herein, a first functionalized molecule covers at least a portion of the first surface, and a second functionalized molecule covers at least a portion of the second surface. In some embodiments, the first functionalized molecule is a functionalized hydrogel or polymer comprising a plurality of first functional groups, the second functionalized molecule is a functionalized hydrogel or polymer comprising a plurality of second functional groups, and wherein the first functional groups are orthogonal to the second functional groups.

In some embodiments of the patterned substrate described herein, the first thickness of the imprint layer is about 0 nm to about 200 nm. In some further embodiments, the first thickness of the imprint layer allows sufficient passage of a light having a wavelength between about 225 nm and about 375 nm, or between about 250 nm to about 350 nm. In some embodiments, the percentage transmittal of the light through the first thickness of the imprint layer is at least 85%. In some embodiments, the second thickness of the imprint layer is from about 350 nm to about 800 nm. In some further embodiments, the second thickness of the imprint layer sufficiently blocks passage of a light having a wavelength between about 225 nm and about 375 nm or between about 250 nm to about 350 nm. In some embodiments, the second thickness of the imprint layer is configured to block light by absorption.

In some embodiments of the patterned substrate described herein, the imprint layer comprises polyhedral oligomeric silsesquioxane (POSS). In some further embodiments, the imprint layer comprises one or more photoacid generators (PAG) or photo initiators (PI), or a combination thereof. In some further embodiments, the one or more photoacid generators are selected from the group consisting of bis(4-methylphenyl)iodonium hexafluorophosphate, tris(4-((4-acetylphenyl)thio)phenyl)-sulfonium tetrakis(perfluorophenyl)borate, 2-isopropylthioxanthone, TEGO® 1467, 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate, and combination thereof. In some such embodiments, the imprint layer comprises at least 1% photo acid generator by weight. In some embodiments, the one or more photo initiators are selected from the group consisting of diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphine oxide, ethyl(2,4,6-trimethylbenzoyl) phenylphosphinate, 4,4′-bis(diethylamino)benzophenone, benzoin ethyl ether, 2,2-diethoxyacetophenone, and 4′-phenoxyacetophenone, and combination thereof. In some such embodiments, the imprint layer comprises at least 1% photo initiator by weight. In some embodiments, the imprint layer further comprises at least one leveling agent (LA). In further embodiments, the leveling agent includes a polyacrylate or a polyacrylate co-polymer. In yet further embodiments, the leveling agent is selected from the group consisting of BYK-350 (BYK-Chemic GmbH), BYK-394 (BYK-Chemic GmbH), BYK-354 (BYK-Chemic GmbH), BYK-392 (BYK-Chemic GmbH), BYK-352 (BYK-Chemic GmbH), BYK-356 (BYK-Chemie GmbH), and BYK-359 (BYK-Chemic GmbH), and combinations thereof.

In some other embodiments of the patterned substrate described herein, the second thickness is configured to block light by reflection. In some such embodiments, the imprint layer comprises a stack of alternating layers of a first material and a second material, the first material having a first refractive index and the second material having a second refractive index, the first refractive index higher than the second refractive index. In some such embodiments, the second thickness of the imprint layer comprises at least seven alternating layers of the stack. In some such embodiments, the first material comprises Si₃N₄ and the second material comprises SiO₂. In some such embodiments, each layer of the stack of the first material has a thickness of about 38 nm, and each layer of the second material has a thickness of about 55 nm. In some other embodiments, the first material and the second material may include POSS or nanoimprint lithography (NIL) resin materials with different refractive indexes (e.g., different opacities).

In any embodiments of the patterned substrate described herein, the plurality of multi-level depressions are multi-level nanowells. In some embodiments, the base support is transparent. In some embodiments, the base support comprising a glass.

Another aspect of the present disclosure relates to a method for patterning a surface of a substrate, comprising:
introducing a photoresist to a substrate, the substrate comprising an imprint layer positioned over a base support, the imprint layer comprising a plurality of multi-level depressions, each depression comprising a deep portion having a first surface and a shallow portion having a second surface, where distance between the first surface and the base support corresponds to a first thickness of the imprint layer, the distance between the second surface and the base support corresponds to a second thickness of the imprint layer, and the second thickness is greater than the first thickness, and wherein the photoresist resides within at least a portion of the multi-level depressions;
exposing the substrate to light from a backside of the base support opposite to the imprint layer, the first thickness of the imprint layer configured to allow passage of the light to cure at least a portion of the photoresist resided within the deep portion of the multi-level depressions, and the second thickness of the imprint layer configured to sufficiently block passage of the light such that the photoresist resided within the shallow portion of the multi-level depressions remain uncured; and
removing the uncured photoresist from the substrate to expose the second surface of the multi-level depressions.

In some embodiments of the method described herein, the photoresist is a negative photoresist. In some embodiments, exposing the substrate to light generates a crosslinked photoresist positioned over the first surface of the deep portion of the multi-level depressions. In some embodiments, the method further comprises:
depositing a first functionalized molecule over the imprint layer to cover both the cross-linked photoresist and at least a portion of the second surface of the multi-level depressions;
removing the crosslinked photoresist in the deep portion of the multi-level depressions to expose the first surface of the multi-level depressions; and
depositing a second functionalized molecule over at least a portion of the first surface of the multi-level depressions.

In some embodiments of the method described herein, the first thickness of the imprint layer is about 0 nm to about 200 nm. In some further embodiments, the first thickness of the imprint layer allows sufficient passage of a light having a wavelength between about 225 nm and about 375 nm, or between about 250 nm to about 350 nm. In some embodiments, the percentage transmittal of the light through the first thickness of the imprint layer is at least 85%. In some embodiments, the second thickness of the imprint layer is from about 350 nm to about 800 nm. In some further embodiments, the second thickness of the imprint layer sufficiently blocks passage of a light having a wavelength between about 225 nm and about 375 nm or between about 250 nm to about 350 nm.

In some embodiments of the method described herein, the second thickness of the imprint layer is configured to block light by absorption. In some embodiments, the imprint layer comprises polyhedral oligomeric silsesquioxane (POSS). In some further embodiments, the imprint layer comprises one or more photoacid generators (PAG) or photo initiators (PI), or a combination thereof. In some further embodiments, the one or more photoacid generators are selected from the group consisting of bis(4-methylphenyl)iodonium hexafluorophosphate, tris(4-((4-acetylphenyl)thio)phenyl)-sulfonium tetrakis(perfluorophenyl)borate, 2-isopropylthioxanthone, TEGO® 1467, 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate, and combination thereof. In some such embodiments, the imprint layer comprises at least 1% photo acid generator by weight. In some embodiments, the one or more photo initiators are selected from the group consisting of diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphinc oxide, ethyl(2,4,6-trimethylbenzoyl) phenylphosphinate, 4,4′-bis(dicthylamino)benzophenone, benzoin ethyl ether, 2,2-diethoxyacetophenone, and 4′-phenoxyacetophenone, and combination thereof. In some such embodiments, the imprint layer comprises at least 1% photo initiator by weight. In some embodiments, the imprint layer further comprises at least one leveling agent (LA). In further embodiments, the leveling agent includes a polyacrylate or a polyacrylate co-polymer. In yet further embodiments, the leveling agent is selected from the group consisting of BYK-350 (BYK-Chemic GmbH), BYK-394 (BYK-Chemic GmbH), BYK-354 (BYK-Chemic GmbH), BYK-392 (BYK-Chemic GmbH), BYK-352 (BYK-Chemic GmbH), BYK-356 (BYK-Chemic GmbH), and BYK-359 (BYK-Chemic GmbH), and combinations thereof.

In some other embodiments of the method described herein, the second thickness is configured to block light by reflection. In some such embodiments, the imprint layer comprises a stack of alternating layers of a first material and a second material, the first material having a first refractive index and the second material having a second refractive index, the first refractive index higher than the second refractive index. In some such embodiments, the second thickness of the imprint layer comprises at least seven alternating layers of the stack. In some such embodiments, the first material comprises Si₃N₄ and the second material comprises SiO₂. In some such embodiments, each layer of the stack of the first material has a thickness of about 38 nm, and each layer of the second material has a thickness of about 55 nm. In some other embodiments, the first material and the second material may include POSS or nanoimprint lithography (NIL) resin materials with different refractive indexes (e.g., different opacities).

In any embodiments of the method described herein, the plurality of multi-level depressions are multi-level nanowells. In some embodiments, the method does not include an etching step.

### BRIEF DESCRIPTION OF THE DRAWINGS

FIG. 1 schematically illustrates an etch-free workflow to prepare a patterned substrate according to an embodiment of the present disclosure.

FIG. 2 schematically illustrates a photocuring step of the process illustrated in FIG. 1.

FIG. 3 schematically illustrates a second example etch-free workflow to prepare a patterned substrate according to an embodiment of the present disclosure.

FIG. 4A schematically illustrates light reflection from interfaces within a dielectric stack of the imprint layer of FIG. 3.

FIG. 4B schematically illustrates a photocuring step of the process illustrated in FIG. 3.

FIG. 5 is a plot of transmissivity of various imprint layer materials for light from 240 nm to 450 nm.

FIGS. 6A-6D show scanning electron microscope images and corresponding light intensity heatmaps within depressions for example substrates in accordance with the present disclosure.

### DETAILED DESCRIPTION

The present disclosure relates to the substrates, and fabrication process thereof. Described herein is an etch-free process of preparing patterned substrate suitable for a SPEAR application. In particular, the substrates disclosed herein include flowcells which may be used for nucleic acid sequencing, in particular sequencing by synthesis. It may be desirable to eliminate an etch step from such a process to reduce cost, time, and/or effort in manufacturing substrates.

The section headings used herein are for organizational purposes only and are not to be construed as limiting the subject matter described.

### Definitions

Unless defined otherwise, all technical and scientific terms used herein have the same meaning as is commonly understood by one of ordinary skill in the art. The use of the term “including” as well as other forms, such as “include,” “includes,” and “included,” is not limiting. The use of the term “having” as well as other forms, such as “have,” “has,” and “had,” is not limiting. As used in this specification, whether in a transitional phrase or in the body of the claim, the terms “comprise(s)” and “comprising” are to be interpreted as having an open-ended meaning. That is, the above terms are to be interpreted synonymously with the phrases “having at least” or “including at least.” For example, when used in the context of a process, the term “comprising” means that the process includes at least the recited steps, but may include additional steps. When used in the context of a compound, composition, or device, the term “comprising” means that the compound, composition, or device includes at least the recited features or components, but may also include additional features or components.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount.

The term “and/or” as used herein has its broadest least limiting meaning, which is the disclosure includes A alone, B alone, both A and B together, or A or B alternatively, but does not require both A and B or require one of A or one of B. As used herein, the phrase “at least one of” A, B, “and” C should be construed to mean a logical A or B or C, using a non-exclusive logical “or.”

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As used herein, common abbreviations are defined as follows:
dATP Deoxyadenosine triphosphate
dCTP Deoxycytidine triphosphate
dGTP Deoxyguanosine triphosphate
dTTP Deoxythymidine triphosphate
PAZAM Poly(N-(5-azidoacetamidylpentyl) acrylamide-co-acrylamide) of any acrylamide to Azapa ratio
SBS Sequencing-by-synthesis

As used herein, the term “attached” refers to the state of two things being joined, fastened, adhered, connected or bound to each other. For example, an analyte, such as a nucleic acid, can be attached to a material, such as a gel or solid support, by a covalent or non-covalent bond. A covalent bond is characterized by the sharing of pairs of electrons between atoms. A non-covalent bond is a chemical bond that does not involve the sharing of pairs of electrons and can include, for example, hydrogen bonds, ionic bonds, van der Waals forces, hydrophilic interactions and hydrophobic interactions.

As used herein, the term “array” refers to a population of different probes (e.g., probe molecules) that are attached to one or more substrates such that the different probes can be differentiated from each other according to relative location. An array can include different probes that are each located at a different addressable location on a substrate. Alternatively or additionally, an array can include separate substrates each bearing a different probe, wherein the different probes can be identified according to the locations of the substrates on a surface to which the substrates are attached or according to the locations of the substrates in a liquid. Further examples of arrays that can be used in the invention include, without limitation, those described in U.S. Pat. Nos. 5,429,807; 5,436,327; 5,561,071; 5,583,211; 5,658,734; 5,837,858; 5,874,219; 5,919,523; 6, 136,269; 6,287,768; 6,287,776; 6,288,220; 6,297,006; 6,291,193; 6,346,413; 6,416,949; 6,482,591; 6,514,751; and 6,610,482; WO 93/17126; WO 95/11995; WO 95/35505; EP 742 287; and EP 799 897.

As used herein, the term “covalently attached” or “covalently bonded” refers to the forming of a chemical bonding that is characterized by the sharing of pairs of electrons between atoms. For example, a covalently attached hydrogel refers to a hydrogel that forms chemical bonds with a functionalized surface of a substrate, as compared to attachment to the surface via other means, for example, adhesion or electrostatic interaction. It will be appreciated that polymers that are attached covalently to a surface can also be bonded via means in addition to covalent attachment.

As used herein, the term “non-covalent interactions” differs from a covalent bond in that it does not involve the sharing of electrons, but rather involves more dispersed variations of electromagnetic interactions between molecules or within a molecule. Non-covalent interactions can be generally classified into four categories, electrostatic, x-effects, van der Waals forces, and hydrophobic effects. Non-limiting examples of electrostatic interactions include ionic interactions, hydrogen bonding (a specific type of dipole-dipole interaction), halogen bonding, etc. Van der Walls forces are a subset of electrostatic interaction involving permanent or induced dipoles or multipoles. π-effects can be broken down into numerous categories, including (but not limited to) π-π interactions, cation-π and anion-π interactions, and polar-π interactions. In general, π-effects are associated with the interactions of molecules with the π-orbitals of a molecular system, such as benzene. The hydrophobic effect is the tendency of nonpolar substances to aggregate in aqueous solution and exclude water molecules. Non-covalent interactions can be both intermolecular and intramolecular. Non-covalent interactions can be both intermolecular and intramolecular.

As used herein, the term “coat,” when used as a verb, is intended to mean providing a layer or covering on a surface. At least a portion of the surface can be provided with a layer or cover. In some cases, the entire surface can be provided with a layer or cover. In alternative cases only a portion of the surface will be provided with a layer or covering. The term “coat,” when used to describe the relationship between a surface and a material, is intended to mean that the material is present as a layer or cover on the surface. The material can seal the surface, for example, preventing contact of liquid or gas with the surface. However, the material need not form a seal. For example, the material can be porous to liquid, gas, or one or more components carried in a liquid or gas. Exemplary materials that can coat a surface include, but are not limited to, a gel, polymer, organic polymer, liquid, metal, a second surface, plastic, silica, or gas.

As used herein the term “analyte” is intended to include any of a variety of analytes that are to be detected, characterized, modified, synthesized, or the like. Exemplary analytes include, but are not limited to, nucleic acids (e.g., DNA, RNA or analogs thereof), proteins, polysaccharides, cells, nuclei, cellular organelles, antibodies, epitopes, receptors, ligands, enzymes (e g kinases, phosphatases or polymerases), peptides, small molecule drug candidates, or the like. An array can include multiple different species from a library of analytes. For example, the species can be different antibodies from an antibody library, nucleic acids having different sequences from a library of nucleic acids, proteins having different structure and/or function from a library of proteins, drug candidates from a combinatorial library of small molecules, etc.

As used herein, directional language, for example “over,” “above,” “below,” “top,” and “bottom,” are meant to indicate directions with respect to the substrates as depicted in the figures. For instance, generally the base layer/base support is regarded herein as being at the bottom of the substrate, with other layers being layered over and/or above the base layer. Directional language herein is meant only to be descriptive with reference to the figures and is not intended to be limiting. For example, some embodiments may be implemented such that the base layer is the top surface and that the other layers, for example the imprint layer, are below the base layer.

As used herein the term “contour” is intended to mean a localized variation in the shape of a surface. Exemplary contours include, but are not limited to, wells, pits, channels, posts, pillars, and ridges. Contours can occur as any of a variety of depressions in a surface or projections from a surface. All or part of a contour can serve as a feature in an array. For example, a part of a contour that occurs in a particular plane of a solid support can serve as a feature in that particular plane. In some embodiments, contours are provided in a regular or repeating pattern on a surface.

As used herein, the term “depression” refers to a discrete concave contour in a patterned support having a surface opening that is completely surrounded by interstitial region(s) of the patterned support surface. Depressions can have any of a variety of shapes at their opening in a surface including, as examples, round, elliptical, square, polygonal, star shaped (with any number of vertices), etc. The cross-section of a depression taken orthogonally with the surface can be curved, square, polygonal, hyperbolic, conical, angular, stepped, etc. For example, the wells described herein are considered as depressions.

Where a material is “within” a contour, it is located in the space of the contour. For example, for a depression such as a well, the material is inside the well, and for a projection such as a pillar or post, the material covers the contour that extends above the plane of the surface.

As used herein, the term “different,” when used in reference to nucleic acids, means that the nucleic acids have nucleotide sequences that are not the same as each other. Two or more nucleic acids can have nucleotide sequences that are different along their entire length. Alternatively, two or more nucleic acids can have nucleotide sequences that are different along a substantial portion of their length. For example, two or more nucleic acids can have target nucleotide sequence portions that are different for the two or more molecules while also having a universal sequence portion that is the same on the two or more molecules. The term can be similarly applied to proteins which are distinguishable as different from each other based on amino acid sequence differences.

As used herein, the term “cach,” when used in reference to a collection of items, is intended to identify an individual item in the collection but does not necessarily refer to every item in the collection. Exceptions can occur if explicit disclosure or context clearly dictates otherwise.

As used herein, the term “feature” means a location in an array that is configured to attach a particular analyte. For example, a feature can be all or part of a contour on a surface. A feature can contain only a single analyte, or it can contain a population of several analytes, optionally the several analytes can be the same species. In some embodiments, features are present on a solid support prior to attaching an analyte. In other embodiments the feature is created by attachment of an analyte to the solid support.

As used herein, the term “flow cell” is intended to mean a vessel having a chamber where a reaction can be carried out, an inlet for delivering reagents to the chamber and an outlet for removing reagents from the chamber. In some embodiments, the chamber is configured for detection of the reaction that occurs in the chamber (e.g., on a surface that is in fluid contact with the chamber). For example, the chamber can include one or more transparent surfaces allowing optical detection of arrays, optically labeled molecules, or the like in the chamber. Exemplary flow cells include but are not limited to those used in a nucleic acid sequencing apparatus such as flow cells for the Genome Analyzer®, MiSeq®, NextSeq® or HiSeq® platforms commercialized by Illumina, Inc. (San Diego, CA); or for the SOLID™ or Ion Torrent™ sequencing platform commercialized by Life Technologies (Carlsbad, CA). Exemplary flow cells and methods for their manufacture and use are also described, for example, in WO 2014/142841 A1; U.S. Pat. App. Pub. No. 2010/0111768 A1 and U.S. Pat. No. 8,951,781, each of which is incorporated herein by reference.

As used herein, the term “hydrogel” or “gel material” is intended to mean a semi-rigid material that is permeable to liquids and gases. Typically, a hydrogel material can swell when liquid is taken up and can contract when liquid is removed, e.g., by drying. Exemplary hydrogels include, but are not limited to, those having a colloidal structure, such as agarose; polymer mesh structure, such as gelatin; or cross-linked polymer structure, such as polyacrylamide, silane free acrylamide (see, for example, US Pat. App. Pub. No. 2011/0059865 A1), PAZAM (see, for example, U.S. Pat. No. 9,012,022, which is incorporated herein by reference), and polymers described in U.S. Patent Pub. Nos. 2015/0005447 and 2016/0122816, all of which are incorporated by reference in their entireties. Particularly useful gel material will conform to the shape of a well or other contours where it resides. Some useful hydrogel materials can both (a) conform to the shape of the well or other contours where it resides and (b) have a volume that does not substantially exceed the volume of the well or contours where it resides.

As used herein, the term “interstitial region” refers to an area in a substrate or on a surface that separates other areas of the substrate or surface. The interstitial region does not allow for the binding of library DNA. For example, an interstitial region can separate one library DNA binding region from another library DNA binding region. The two regions that are separated from each other can be discrete, lacking contact with each other. In some embodiments the interstitial region is continuous whereas the contours or features are discrete, for example, as is the case for an array of wells in an otherwise continuous surface. The separation provided by an interstitial region can be partial or full separation. Interstitial regions may have a surface material that differs from the surface material of the contours or features on the surface. For example, contours of an array can have an amount or concentration of gel material or analytes that exceeds the amount or concentration present at the interstitial regions.

As used herein, the terms “nucleic acid” and “nucleotide” are intended to be consistent with their use in the art and to include naturally occurring species or functional analogs thereof. Particularly useful functional analogs of nucleic acids are capable of hybridizing to a nucleic acid in a sequence specific fashion or capable of being used as a template for replication of a particular nucleotide sequence. Naturally occurring nucleic acids generally have a backbone containing phosphodiester bonds. An analog structure can have an alternate backbone linkage including any of a variety of those known in the art. Naturally occurring nucleic acids generally have a deoxyribose sugar (e.g., found in deoxyribonucleic acid (DNA)) or a ribose sugar (e.g., found in ribonucleic acid (RNA)). A nucleic acid can contain nucleotides having any of a variety of analogs of these sugar moieties that are known in the art. A nucleic acid can include native or non-native nucleotides. In this regard, a native deoxyribonucleic acid can have one or more bases selected from the group consisting of adenine, thymine, cytosine or guanine and a ribonucleic acid can have one or more bases selected from the group consisting of uracil, adenine, cytosine or guanine. Useful non-native bases that can be included in a nucleic acid or nucleotide are known in the art. The terms “probe” or “target,” when used in reference to a nucleic acid, are intended as semantic identifiers for the nucleic acid in the context of a method or composition set forth herein and does not necessarily limit the structure or function of the nucleic acid beyond what is otherwise explicitly indicated. The terms “probe” and “target” can be similarly applied to other analytes such as proteins, small molecules, cells, or the like.

As used herein, the term “orthogonal” in the context of chemical reaction, it refers to the situation when there are two pairs of substances and each substance can interact with their respective partner, but does not interact with either substance of the other pair. In the context of the first and the second functionalized molecules, it refers to that the first functional groups of the first functionalized molecule will selectively react with certain chemical entities, while the second functional groups of the second functionalized molecule will have little or no reactivity towards the same chemical entities that are reactive to the first functional groups of the first functionalized molecule.

As used herein, the term “surface” is intended to mean an external part or external layer of a solid support or gel material. The surface can be in contact with another material such as a gas, liquid, gel, polymer, organic polymer, second surface of a similar or different material, metal, or coat. The surface, or regions thereof, can be substantially flat or planar. The surface can have surface contours such as wells, pits, channels, ridges, raised regions, pegs, posts or the like.

As used herein, the “solid support” or “substrate” may be used interchangeably and both refer to a rigid substrate that is insoluble in aqueous liquid. The substrate can be non-porous or porous. The solid support can optionally be capable of taking up a liquid (e.g., due to porosity) but will typically be sufficiently rigid that the substrate does not swell substantially when taking up the liquid and does not contract substantially when the liquid is removed by drying. A nonporous solid support is generally impermeable to liquids or gases. Exemplary solid supports include, but are not limited to, glass and modified or functionalized glass, plastics (e.g., acrylics, polystyrene and copolymers of styrene and other materials, polypropylene, polyethylene, polybutylene, polyurethanes, Teflon™, cyclic olefins, polyimides, etc.), nylon, ceramics, resins, Zeonor, silica or silica-based materials including silicon and modified silicon, carbon, metals, inorganic glasses, optical fiber bundles, and polymers. A particularly useful material is glass. Other suitable substrate materials may include polymeric materials, plastics, silicon, quartz (fused silica), borofloat glass, silica, silica-based materials, carbon, metals including gold, an optical fiber or optical fiber bundles, sapphire, or plastic materials such as COCs and epoxies. The particular material can be selected based on properties desired for a particular use. For example, materials that are transparent to a desired wavelength of radiation are useful for analytical techniques that will utilize radiation of the desired wavelength, such as one or more of the techniques set forth herein. Conversely, it may be desirable to select a material that does not pass radiation of a certain wavelength (e.g., being opaque, absorptive or reflective). This can be useful for formation of a mask to be used during manufacture of the structured substrate; or to be used for a chemical reaction or analytical detection carried out using the structured substrate. Other properties of a material that can be exploited are inertness or reactivity to certain reagents used in a downstream process; or case of manipulation or low cost during a manufacturing process manufacture. Further examples of materials that can be used in the structured substrates or methods of the present disclosure are described in US Pat. App. Pub. No. 2012/0316086 A1 and 2013/0116153, each of which is incorporated herein by reference.

As used herein, the term “well” refers to a discrete contour in a solid support having a surface opening that is completely surrounded by interstitial region(s) of the surface. Wells can have any of a variety of shapes at their opening in a surface including but not limited to round, elliptical, square, polygonal, star shaped (with any number of vertices), etc. The cross section of a well taken orthogonally with the surface can be curved, square, polygonal, hyperbolic, conical, angular, etc. In some embodiments, the well is a microwell or a nanowell.

As used herein, the term “clustering oligonucleotide” or “clustering primer” refers to nucleotide sequence immobilized on the surface of the solid support used for amplifying the template polynucleotides to create identical copies of the same templates (i.e., clusters). Examples of clustering oligonucleotide may include but not limited to P5 primer, P7 primer, P15 primer, P17 primer as described herein. In some embodiments, the “clustering primer” is also referred to as a “surface primer.”

The P5 and P7 primers are used on the surface of commercial flow cells sold by Illumina Inc. The P5 and/or P7 primers, can be used for sequencing on HiSeq™, HiSeqX™, MiSeq™, MiSeqDX™, MiniSeq™, NextSeq™, NextSeqDX™, NovaSeq™, Genome Analyzer™, ISEQ™, and other instrument platforms. These primers are also referred to as the “clustering primers” or “clustering oligonucleotides.” The primer sequences are described in U.S. Pat. Pub. No. 2011/0059865 A1, which is incorporated herein by reference. The P5 and P7 primer sequences comprise the following:
Paired end set:

P5: paired end 5′→3′
SEQ ID NO. 1:
AATGATACGGCGACCACCGAGAUCTACAC
P7: paired end 5′→3′
SEQ ID NO. 2:
CAAGCAGAAGACGGCATACGAGAT

Single read set:

P5: single read 5′→3′
SEQ ID NO. 3:
AATGATACGGCGACCACCGA
P7: single read 5′→3′
SEQ ID NO. 4:
CAAGCAGAAGACGGCATACGA

In some embodiments, the P5 and P7 primers may comprise a linker or spacer at the 5′ end. Such linker or spacer may be included in order to permit cleavage, or to confer some other desirable property, for example to enable covalent attachment to a polymer or a solid support, or to act as spacers to position the site of cleavage an optimal distance from the solid support. In certain cases, 10-50 spacer nucleotides may be positioned between the point of attachment of the P5 or P7 primers to a polymer or a solid support. In some embodiments polyT spacers are used, although other nucleotides and combinations thereof can also be used. TET is a dye labeled oligonucleotide having complementary sequence to the P5/P7 primers. TET can be hybridized to the P5/P7 primers on a surface; the excess TET can be washed away, and the attached dye concentration can be measured by fluorescence detection using a scanning instrument such as a Typhoon Scanner (General Electric). In addition to the P5/P7 primers, other non-limiting examples of the sequencing primer sequences such as P15/P17 primers have also been disclosed in U.S. Publication No. 2019/0352327. These additional clustering primers comprise the following:

P15: 5′→3′
SEQ ID NO. 5:
AATGATACGGCGACCACCGAGAT*CTACAC

where T* refers to an allyl modified T.

P17: 5′→3′
SEQ ID NO. 6:
YYYCAAGCAGAAGACGGCATACGAGAT

where Y is a diol linker subject to chemical cleavage, for example, by oxidation with a reagent such as periodate, as disclosed in U.S. Publication No. 2012/0309634, which is incorporated by preference in its entirety.

As used herein, the term “amino” refers to a “—NR_{A}R_{B}” group in which R_{A} and R_{B} are each independently selected from hydrogen, C₁₋₆ alkyl, C₂₋₆ alkenyl, C₂₋₆ alkynyl, C₃₋₇ carbocyclyl, C₆₋₁₀ aryl, 5-10 membered heteroaryl, and 5-10 membered heterocyclyl, as defined herein. A non-limiting example includes free amino (i.e., —NH₂).

As used herein, the term “azido” refers to a —N₃ group.

As used herein, the term “carboxyl” refers to a —C(═O)OH group.

As used herein, the term “thiol” refers to a —SH group.

As used herein, “vinyl” refers to a —CH═CH₂ group.

As used herein, the term “epoxy” as used herein refers to

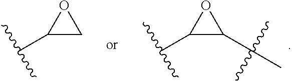

As used herein, the term “glycidyl” as used herein refers to

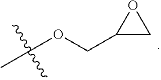 [SMILES: *OCC1CO1]

The embodiments set forth herein and recited in the claims can be understood in view of the above definitions.

### Patterned Substrate

One aspect of the present disclosure relates to a patterned substrate, comprising:
a base support;
an imprint layer positioned over the base support, the imprint layer comprising a plurality of multi-level depressions, each depression comprising a deep portion having a first surface (e.g., parallel to the base support), and a shallow portion having a second surface (e.g., parallel to the base support), the deep portion and the shallow portion are defined by a step portion, wherein distance between the first surface and the base support corresponds to a first thickness of the imprint layer, the distance between the second surface and the base support corresponds to a second thickness of the imprint layer, and the second thickness is greater than the first thickness;
wherein the first thickness of the imprint layer is configured to allow sufficient passage of light to the deep portion of the depression to crosslink a photoresist, and the second thickness of the imprint layer is configured to sufficiently block passage of light to the shallow portion of the depression to inhibit crosslinking of the photoresist.

### Functionalized Molecules

In some embodiments of the patterned substrate described herein, a first functionalized molecule covers at least a portion of the first surface, and a second functionalized molecule covers at least a portion of the second surface. In some embodiments, the first functionalized molecule is a functionalized hydrogel or polymer comprising a plurality of first functional groups, the second functionalized molecule is a functionalized hydrogel or polymer comprising a plurality of second functional groups, and wherein the first functional groups are orthogonal to the second functional groups. In some embodiments, the functionalized molecule includes a functionalized hydrogel. In some embodiments, the functionalized molecule includes a functionalized polymer.

The functionalized hydrogel described herein may comprise two or more recurring monomer units in any order or configuration, and may be linear, cross-linked, or branched, or a combination thereof. In an example, the polymer may be a heteropolymer and the heteropolymer may include an acrylamide monomer, such as

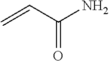

or a substituted analog thereof. The polymer or hydrogel may be coated on the surface either by covalent or non-covalent attachment.

In some embodiments, the hydrogel comprises the repeating units of:

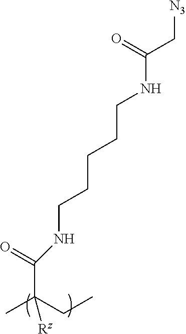

and optionally

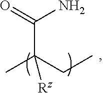

where each R^{z} is independently H or C₁-C₄ alkyl. In an example, a polymer used may include examples such as a poly(N-(5-azidoacetamidylpentyl)acrylamide-co-acrylamide), also known as PAZAM:

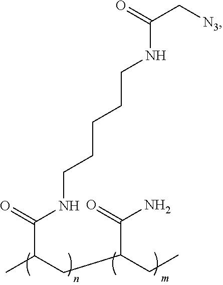

wherein n is an integer in the range of 1-20,000, and m is an integer in the range of 1-100,000. In some examples, the acrylamide monomer may include an azido acetamido pentyl acrylamide monomer:

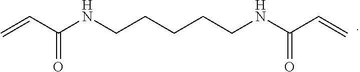

In some examples, the hydrogel may comprise repeating units of

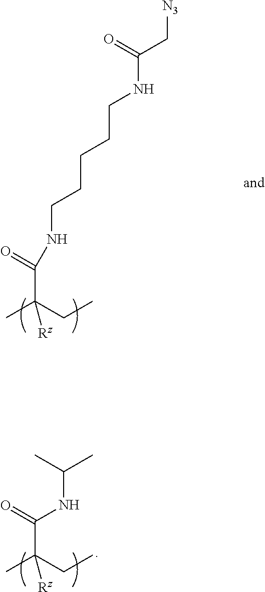

In further embodiments, the hydrogel may comprise the structure:

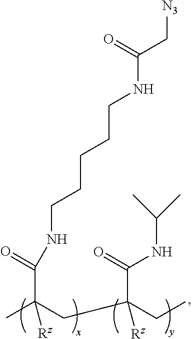

wherein x is an integer in the range of 1-20,000, and y is an integer in the range of 1-100,000, or

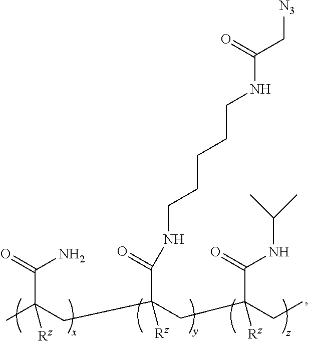

wherein y is an integer in the range of 1-20,000 and x and z are integers wherein the sum of x and z may be within a range of from 1 to 100,000, where each R^{z} is independently H or C₁₋₄ alkyl and a ratio of x:y may be from approximately 10:90 to approximately 1:99, or may be approximately 5:95, or a ratio of (x:y):z may be from approximately 85:15 to approximately 95:5, or may be approximately 90:10 (wherein a ratio of x:(y:z) may be from approximately 1:(99) to approximately 10:(90), or may be approximately 5:(95)), respectively.

In an example, the polymeric hydrogel includes an acrylamide copolymer, such as PAZAM. The molecular weight of PAZAM and other forms of the acrylamide copolymer may range from about 5 kDa to about 1500 kDa or from about 10 kDa to about 1000 kDa, or may be, in a specific example, about 312 kDa. In some examples, PAZAM and other forms of the acrylamide copolymer are linear polymers. In some other examples, PAZAM and other forms of the acrylamide copolymer are a lightly cross-linked polymers.

As still another example, the hydrogel may include a recurring unit of each of structure (III) and (IV):

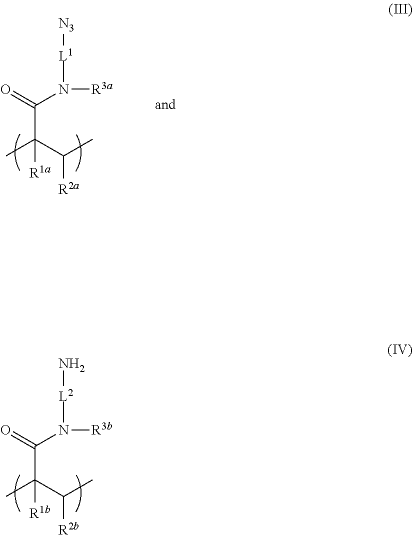

wherein each of R^{1a}, R^{2a}, R^{1b} and R^{2b} is independently selected from hydrogen, an optionally substituted alkyl or optionally substituted phenyl; each of R^{3a} and R^{3b} is independently selected from hydrogen, an optionally substituted alkyl, an optionally substituted phenyl, or an optionally substituted C₇-C₁₄ aralkyl; and each L¹ and L² is independently selected from an optionally substituted alkylene linker or an optionally substituted heteroalkylene linker.

In some embodiments of the patterned substrate described herein, at least a portion of the multi-level depressions are multi-level nanowells, each nanowell comprising a deep well and a shallow well.

In some embodiments of the patterned substrate described herein, the base support comprises a glass. In some embodiments of the patterned substrate described herein, the base support may be transparent. The base support may include any suitable material. The base support 102 may be optically transparent. The base support may be optically transparent to at least a wavelength capable of photocuring a photoresist. Examples of suitable materials for the base support include epoxy siloxane, glass and modified or functionalized glass, plastics (including acrylics, polystyrene and copolymers of styrene and other materials, polypropylene, polyethylene, polybutylene, polyurethanes, polytetrafluoroethylene (such as TEFLON® from Chemours), cyclic olefins/cyclo-olefin polymers (COP) (such as ZEONOR® from Zeon), polyimides, etc.), nylon, ceramics/ceramic oxides, silica, fused silica, or silica-based materials, aluminum silicate, silicon and modified silicon (e.g., boron doped p+ silicon), silicon nitride (Si₃N₄), silicon oxide (SiO₂), tantalum pentoxide (Ta₂O₅) or other tantalum oxide(s) (TaOx), hafnium oxide (HfO₂), carbon, metals, inorganic glasses, or the like. The base support 102 may also be a multi-layered structure. Some examples of the multi-layered structure include glass or silicon, with a coating layer of tantalum oxide or another ceramic oxide at the surface. Still other examples of the multi-layered structure may include a silicon-on-insulator (SOI) substrate.

### Imprint Layer

In some embodiments of the patterned substrate described herein, the imprint layer may include any suitable material in accordance with the present disclosure. The imprint layer may include a resin material. The resin material may be, for example, a nanoimprinting lithography (NIL) resin. In one aspect, the present disclosure provides materials as an imprint layer for preparing a surface of a substrate (e.g., a flow cell) that avoids an etch step. The imprint layer may also be referred to herein as the nanoimprint lithography (NIL) layer. It may be advantageous to include materials in the imprint layer that, beyond a certain thickness, are capable of blocking light.

In some embodiments, the imprint layer may include a silsesquioxane. As used herein, the term “polyhedral oligomeric silsesquioxane,” (“POSS,” commercially available from Hybrid Plastics), refers to a chemical composition that is a hybrid intermediate (e.g., RSiO_{1.5}) between that of silica (SiO₂) and silicone (R₂SiO). An example of POSS may be that described in Kehagias et al., Stamp replication for thermal and UV nanoimprint lithography using a UV-sensitive silsesquioxane resist, Microelectronic Engineering 86, 776-78 (2009), which is incorporated by reference herein in its entirety. In an example, the composition is an organosilicon compound with the chemical formula [RSiO_{3/2}]ₙ, where the R groups can be the same or different. Example R groups for POSS include epoxy, azide/azido, a thiol, a poly(ethylene glycol), a norbornene, a tetrazine, acrylates, and/or methacrylates, or further, for example, alkyl, aryl, alkoxy, and/or haloalkyl groups.

The imprint layer may include an epoxy material. Any suitable epoxy monomer or cross-linkable epoxy copolymer may be used as the epoxy material. The epoxy material may be selected from an epoxy functionalized silsesquioxane (described further hereinbelow). For example,
trimethylolpropane triglycidyl ether:

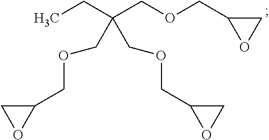 [SMILES: CCC(COCC1CO1)(COCC1CO1)COCC1CO1]

tetrakis(epoxycyclohexyl ethyl)tetramethyl cyclotetrasiloxane:

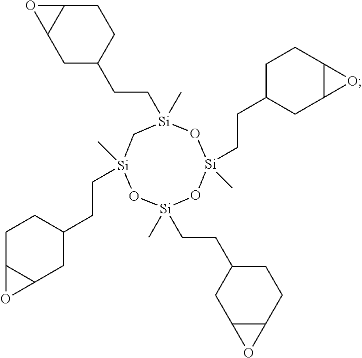 [SMILES: C[Si]1(CCC2CCC3OC3C2)C[Si](C)(CCC2CCC3OC3C2)O[Si](C)(CCC2CCC3OC3C2)O[Si](C)(CCC2CCC3OC3C2)O1]

a copolymer of (epoxycyclohexylethyl)methylsiloxane and dimethylsiloxane:

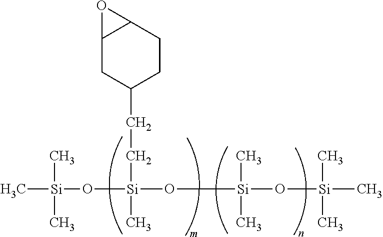

(wherein a ratio of m:n ranges from 8:92 to 10:90);
1,3-bis[2-(3,4-epoxycyclohexyl) ethyl] tetramethyl disiloxane:

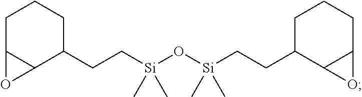 [SMILES: C[Si](C)(CCC1CCCC2OC12)O[Si](C)(C)CCC1CCCC2OC12]

1,3-bis(glycidoxypropyl)tetramethyl disiloxane:

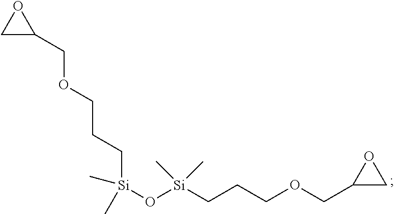 [SMILES: C[Si](C)(CCCOCC1CO1)O[Si](C)(C)CCCOCC1CO1]

3,4-epoxycyclohexylmethyl-3,4-epoxycyclo-hexanecarboxylate:

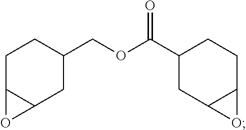 [SMILES: O=C(OCC1CCC2OC2C1)C1CCC2OC2C1]

bis((3,4-epoxycyclohexyl)methyl) adipate:

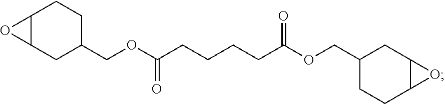 [SMILES: O=C(CCCCC(=O)OCC1CCC2OC2C1)OCC1CCC2OC2C1]

4-vinyl-1-cyclohexene 1,2-epoxide:

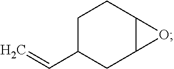

vinylcyclohexene dioxide:

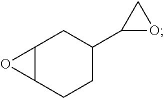

4,5-epoxytetrahydrophthalic acid diglycidylester:

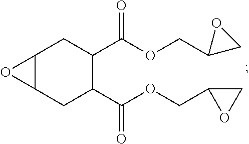 [SMILES: O=C(OCC1CO1)C1CC2OC2CC1C(=O)OCC1CO1]

1,2-epoxy-3-phenoxypropane:

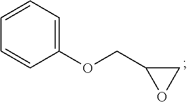 [SMILES: c1ccc(OCC2CO2)cc1]

glycidyl methacrylate:

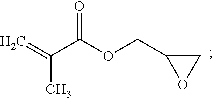

1,2-epoxyhexadecane:

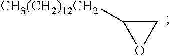

poly(ethylene glycol) diglycidylether:

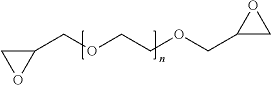

(wherein n ranges from 1 to 100);
pentaerythritol glycidyl ether:

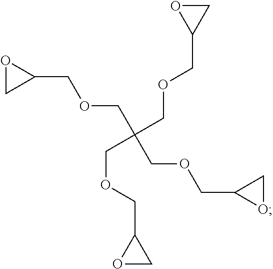 [SMILES: C(OCC(COCC1CO1)(COCC1CO1)COCC1CO1)C1CO1]

diglycidyl 1,2-cyclohexanedicarboxylate:

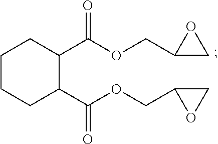 [SMILES: O=C(OCC1CO1)C1CCCCC1C(=O)OCC1CO1]

tetrahydrophthalic acid diglycidyl ester:

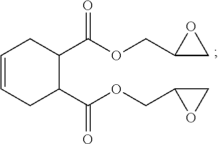 [SMILES: O=C(OCC1CO1)C1CC=CCC1C(=O)OCC1CO1]

and combinations thereof.
   When combinations are used, it is to be understood that any two or more of the listed epoxy resin materials may be used together in the resin composition.

In some embodiments, the epoxy functionalized silsesquioxane includes a silsesquioxane core that is functionalized with epoxy groups. In some embodiments, the imprint layer disclosed herein may comprise one or more different cage or core silsesquioxane structures as monomeric units. For example, the polyhedral structure may be a T₈ structure (a polyoctahedral cage or core structure), such as:

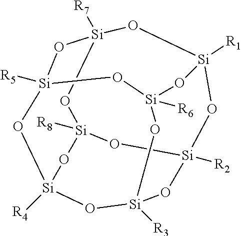

and represented by:

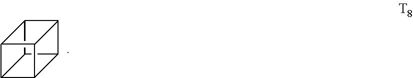

This monomeric unit typically has eight arms of functional groups R₁ through R₈. The monomeric unit may have a cage structure with 10 silicon atoms and 10 R groups, referred to as T₁₀, such as:

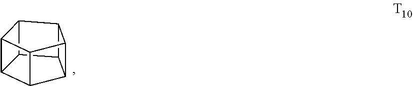

or may have a cage structure with 12 silicon atoms and 12 R groups, referred to as T₁₂, such as:

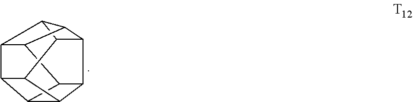 [SMILES: C12C3C4C1C1C5C6C1C2C3C6C54]

The silsesquioxane-based material may alternatively include T₆, T₁₄, or T₁₆ cage structures.

The average cage content can be adjusted during the synthesis, and/or controlled by purification methods, and a distribution of cage sizes of the monomeric unit(s) may be used in the examples disclosed herein. As examples, any of the cage structures may be present in an amount ranging from about 30% to about 100% of the total silsesquioxane monomeric units used. Thus, the silsesquioxane-based material may include a mixture of silsesquioxane configurations.

The silsesquioxane-based material may be a mixture of cage structures, and may include open and partially open cage structures. For example, any epoxy silsesquioxane material described herein may be a mixture of discrete silsesquioxane cages and non-discrete silsesquioxane structures and/or incompletely condensed, discrete structures, such as polymers, ladders, and the like. The partially condensed materials would include epoxy R groups as described herein at some silicon vertices, but some silicon atoms would not be substituted with the epoxy R groups and could be substituted instead with —OH groups. In some examples, the silsesquioxane materials comprise a mixture of various forms, such as:
(a) condensed cages

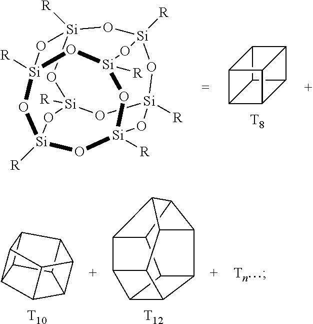

(b) incompletely condensed cages

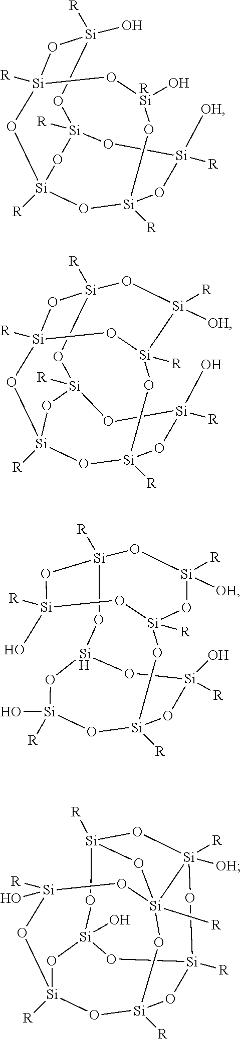

and/or
(c) non-cage content large and ill-defined structure

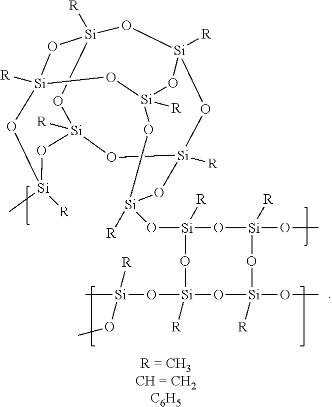

In the examples disclosed herein, at least one of R₁ through R₈ or R₁₀ or R₁₂ comprises an epoxy, and thus the silsesquioxane is referred to as an epoxy silsesquioxane (e.g., epoxy polyhedral oligomeric silsesquioxane). In some aspect, the epoxy silsesquioxane comprises terminal epoxy groups. An example of this type of silsesquioxane is glycidyl POSS having the structure:

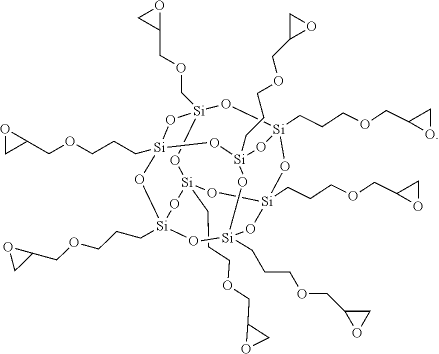 [SMILES: C(COCC1CO1)C[Si]12O[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](COCC2CO2)(O4)O1]

Another example of this type of silsesquioxane is epoxycyclohexyl ethyl functionalized POSS having the structure:

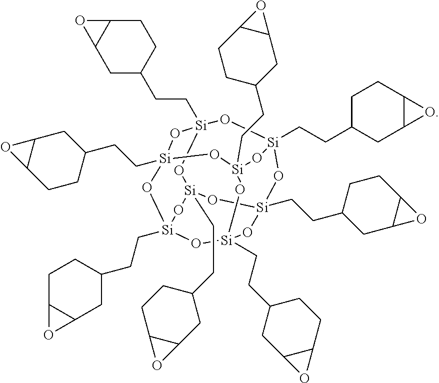 [SMILES: C1CC2OC2CC1CC[Si]12O[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1]

One example of the epoxy resin matrix disclosed herein includes the epoxy functionalized polyhedral oligomeric silsesquioxane, where the epoxy functionalized polyhedral oligomeric silsesquioxane is selected from the group consisting of a glycidyl functionalized polyhedral oligomeric silsesquioxane, an epoxycyclohexyl ethyl functionalized polyhedral oligomeric silsesquioxane, and combinations thereof. This example may include the epoxy silsesquioxane material(s) alone, or in combination with an additional epoxy material selected from the group consisting of trimethylolpropane triglycidyl ether; tetrakis(epoxycyclohexyl ethyl)tetramethyl cyclotetrasiloxane; a copolymer of (epoxycyclohexylethyl)methylsiloxane and dimethylsiloxane; 1,3-bis[2-(3,4-epoxycyclohexyl) ethyl] tetramethyl disiloxane; 1,3-bis(glycidoxypropyl)tetramethyl disiloxane; 3,4-epoxycyclohexylmethyl-3,4-epoxycyclo-hexanecarboxylate; bis((3,4-epoxycyclohexyl)methyl) adipate; 4-vinyl-1-cyclohexene 1,2-epoxide; vinylcyclohexene dioxide; 4,5-epoxytetrahydrophthalic acid diglycidylester; 1,2-epoxy-3-phenoxypropane; glycidyl methacrylate; 1,2-epoxyhexadecane; poly(ethylene glycol) diglycidylether; pentaerythritol glycidyl ether; diglycidyl 1,2-cyclohexanedicarboxylate; tetrahydrophthalic acid diglycidyl ester; and combinations thereof.

In other silsesquioxane examples, a majority of the arms, such as the eight, ten, or twelve arms, or R groups, comprise epoxy groups. In other examples, R₁ through R₈ or R₁₀ or R₁₂ are the same, and thus each of R₁ through R₈ or R₁₀ or R₁₂ comprises an epoxy group. In still other examples, R₁ through R₈ or R₁₀ or R₁₂ are not the same, and thus at least one of R₁ through R₈ or R₁₀ or R₁₂ comprises epoxy and at least one other of R₁ through R₈ or R₁₀ or R₁₂ is a non-epoxy functional group, which in some cases is selected from the group consisting of an azide/azido, a thiol, a poly(ethylene glycol), a norbornene, and a tetrazine, or further, for example, alkyl, aryl, alkoxy, and haloalkyl groups. In some aspect, the non-epoxy functional group is selected to increase the surface energy of the resin. In these other examples, the ratio of epoxy groups to non-epoxy groups ranges from 7:1 to 1:7, or 9:1 to 1:9, or 11:1 to 1:11. In the examples disclosed herein, the epoxy silsesquioxane may also be a modified epoxy silsesquioxane, that includes a controlled radical polymerization (CRP) agent and/or another functional group of interest incorporated into the resin or core or cage structure as one or more of the functional groups R₁ through R₈ or R₁₀ or R₁₂. Whether a single epoxy material or a combination of epoxy materials is used in the epoxy resin matrix, the total amount of the epoxy resin matrix in the resin composition ranges from about 93% to about 99% by weight of the total solids.

With any of the example epoxy materials disclosed herein, it is to be understood that the epoxy group(s) allow the monomeric units and/or the copolymer to polymerize and/or cross-link into a cross-linked matrix upon initiation using a light source (e.g., ultraviolet (UV) light) and acid. The acid may be generated from one or more photoacid generators upon irradiation using a light source (e.g., using ultraviolet (UV) light).

In some embodiments of the imprint layer described herein, beyond a certain thickness, the imprint layer may be capable of blocking light by absorption. The imprint layer may include one or more photoacid generators (PAGs) and/or one or more photo initiators (PIs), or combinations thereof. Photoacid generators are organic compounds that can generate protons (H⁺) upon irradiation with certain wavelengths of light. Photo initiators are molecules that create reactive species (free radicals, cations or anions) when exposed to radiation (UV or visible light). The one or more PAG(s) may be selected from the group including bis(4-methylphenyl)iodonium hexafluorophosphate, tris(4-((4-acetylphenyl)thio)phenyl)-sulfonium tetrakis(perfluorophenyl)borate, 2-isopropylthioxanthone, cationic epoxy silicone (for example, TEGO® Photo Compound 1467), 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PAG(s), or a range defined by any two of the preceding values. In some embodiments, the imprint layer includes from about 0.1% to about 20% PAG(s) by weight, about 0.5% to about 15% PAG(s) by weight, about 1% to about 10% PAG(s) by weight, about 2% to about 9% PAG(s) by weight, about 3% to about 8% PAG(s) by weight, about 4% to about 7% PAG(s) by weight, or about 4% to about 6% PAG(s) by weight. In some embodiments, the imprint layer includes at least 0.1%, 0.5%, 1%, 2%, 3%, 4%, 5%, 6%, 7%, 8%, 9% or 10% of PAG(s) by weight, though in some instances other values or ranges may be used. The PI(s) may be selected from the group including diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphine oxide, ethyl(2,4,6-trimethylbenzoyl) phenylphosphinate, 4,4′-bis(diethylamino)benzophenone, benzoin ethyl ether, 2,2-diethoxyacetophenone, and 4′-phenoxyacetophenone. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PI(s), or a range defined by any two of the preceding values. In some embodiments, the imprint layer includes from about 0.1% to about 20% PI(s) by weight, about 0.5% to about 15% PI(s) by weight, about 1% to about 10% PI(s) by weight, about 2% to about 9% PI(s) by weight, about 3% to about 8% PI(s) by weight, about 4% to about 7% PI(s) by weight, or about 4% to about 6% PI(s) by weight. In some embodiments, the imprint layer includes at least 0.1%, 0.5%, 1%, 2%, 3%, 4%, 5%, 6%, 7%, 8%, 9% or 10% of PI(s) by weight, though in some instances other values or ranges may be used. In some further embodiments, the PAG or PI may have an absorbance range from about 220 nm to about 400 nm, such as about 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm or 400 nm, or a range defined by any two of the preceding values.

In some further embodiments, the imprint layer may be doped with one or more additives to boost the UV-blocking capacity of the etch-free resins. For example, the doped additive(s) may increase the imprintablity of the resins, may result in significant transmittance drop at the photoresist patterning wavelength, increase transparency at visible wavelengths, and/or result in low autofluorescence at sequencable wavelengths. In some embodiments, the one or more additives may be selected from the following table.

| | Absorbance |
|---|---|
| Name of additive | range/nm |
| ZnO particles | 200-400 |
| ZrO₂ particles | 200-400 |
| TiO₂ particles | 200-400 |
| Epoxy compounds of ZnO, ZrO₂, TiO₂ | 200-400 |
| Black hole quenchers ™ (such as 6-carboxyfluorescein | 250-800 |
| (6-FAM), tetrachlorofluorescein (TET), hexachlorofluores- | |
| cein (HEX), etc.) | |
| Carbon particles | 250-800 |
| Avobenzone | 250-400 |
| Bisoctrizole | 260-400 |
| Bismotriznol | 260-400 |
| Meradimate | 250-350 |
| Dioxybenzone | 300-400 |
| Oxybenzone | 280-355 |
| Drometrizole | 300-400 |
| 4-Methacryloxy-2-hydroxybenzophenone | 200-350 |
| 2,2-dihydroxy-4-methoxybenzophenone | 330-370 |
| Drometrizole trisiloxane | 260-400 |
| Methyl-2-cyan-3-(4-hydroxyphenyl)acrylate | 200-400 |
| (E)-Ethyl 2-(3-ethoxy-4-hydroxybenzylidene)-3- | 200-400 |
| oxobutanoate | |
| Ethyl-2-cyano-3-(4-hydroxy-3-methoxy phenyl)acrylate | 200-400 |
| Dimethyl 2-(4-hydroxybenzylidene)malonate | 200-400 |

The imprint layer may include one or more leveling agents (LAs). In some embodiments, the leveling agent is used to enhance the thickness uniformity of the imprint layer. In further embodiments, the leveling agent includes a polyacrylate or a polyacrylate co-polymer. In yet further embodiments, the leveling agent is selected from the group consisting of BYK-350 (BYK-Chemie GmbH), BYK-394 (BYK-Chemie GmbH), BYK-354 (BYK-Chemie GmbH), BYK-392 (BYK-Chemie GmbH), BYK-352 (BYK-Chemie GmbH), BYK-356 (BYK-Chemie GmbH), and BYK-359 (BYK-Chemie GmbH), all of which are polyacrylate-based surface additive for solvent-borne and/or solvent-free coatings. In some embodiments, the imprint layer comprises about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, or 10% leveling agent(s) by weight, or a range defined by any two of the preceding values. In some embodiments, the imprint layer includes from about 0.1% to about 10% LA(s) by weight, about 0.5% to about 8% LA(s) by weight, about 1% to about 6% LA(s) by weight, or about 1.5% to about 4% LA(s) by weight. In some embodiments, the imprint layer includes at least 0.1%, 0.2%, 0.4%, 0.6%, 0.8%, 1%, 1.2%, 1.4%, 1.6%, 1.8%, 2%, 3.0%, 4.0% 5%, 6%, 7%, 8%, 9% or 10% of LA(s) by weight, though in some instances other values or ranges may be used.

### Blocking Light Transmission by Absorption

In some embodiments where the imprint layer is capable of blocking light by absorption, the imprint layer may be capable of blocking light to the photoresist where the imprint layer meets or exceeds a certain threshold thickness. The dose I_{dose} of light transmitted through a thickness of imprint layer can be described by Equation 1:

I_{dose}=Iᵢₙₚᵤₜe^{-4πkt/λ} 1.

where Iᵢₙₚᵤₜ is the dose of light transmitted to the base layer by the light source; k is the extinction coefficient of the imprint layer; t is the thickness of the imprint layer; and λ is the wavelength of the light. The extinction coefficient of the imprint layer k can further be described by Equation 2:

$$2. k \geq \frac{0.183 λ}{γ t}$$

where γ is the contrast of the photoresist. Thus, because the dose of light transmitted I_{dose} is dependent in part on the thickness t of the imprint layer, the thickness t can be chosen to tune the light transmittivity of the imprint layer. The relationship between I₁₀₀, the minimum dose of light required to fully crosslink (i.e., cure and/or photocure) the photoresist and I₀, the maximum dose of light at which photoresist is still completely dissolved can be described by Equation 3:

I₁₀₀=I₀e^{1/γ} 3.

Some embodiments of the present disclosure provide for multi-level depressions in the imprint layer. In accordance with the present disclosure, it may be desirable to choose two different thicknesses t₁ and t₂ for those multi-level depressions. The first thickness t₁ corresponds to the distance between the first surface of the deep portion of the multi-level depression of the imprint layer to the base support. The second thickness t₂ corresponds to the distance between the second surface of the shallow portion of the depression of the imprint layer to the base support. It may be desirable that t₁ is chosen such that, for a given light dosage Iᵢₙₚᵤₜ, the light transmitted is at least I₁₀₀, in accordance with Equation 4:

$$4. {t}_{1} \leq \frac{λ ln ( \frac{{I}_{100}}{{I}_{input}} )}{4 π k}$$

In other words, first thickness t₁ may be chosen to allow sufficient passage of light to the deep portion of the multi-level depression to allow for photocuring of the photoresist at the deep portion. Conversely, it may be desirable that t₂ is chosen such that, for a given light dosage Iᵢₙₚᵤₜ, the light transmitted is less than I₀ in accordance with Equation 5:

$$5. {t}_{2} \geq - \frac{λ ln ( \frac{{I}_{0}}{{I}_{input}} )}{4 π k}$$

In other words, second thickness t₂ may be chosen to sufficiently block light to the shallow portion of the multi-level depression such that the photoresist does not cure at the shallow portion. The dose of light transmitted to the base support by the light source Iᵢₙₚᵤₜ can be tuned by altering an intensity of the light source or a duration of exposure. For example, increasing the intensity of the light source may increase Iᵢₙₚᵤₜ while decreasing the intensity of the light source may decrease Iᵢₙₚᵤₜ. As an example, increasing the duration of exposure may increase Iᵢₙₚᵤₜ decreasing the duration of exposure may decrease Iᵢₙₚᵤₜ. In some embodiments of the patterned substrate described herein, the first thickness of the imprint layer is from about 0 nm to about 200 nm. For example, the first thickness may be about 5 nm, 10 nm, 15 nm 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm or 200 nm, or a range defined by any two of the preceding values. In some further embodiments, the first thickness of the imprint layer allows sufficient passage of a light having a wavelength between about 225 nm and about 375 nm, or between about 250 nm to about 350 nm. In some embodiments, the percentage transmittal of the light through the first thickness of the imprint layer is at least 70%, 75%, 80%, 85%, 90%, 95% or 99%. In some embodiments, the second thickness of the imprint layer is from about 350 nm to about 800 nm. For example, the second thickness may be about 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610nm, 620 nm, 630 nm, 640 nm, 650 nm, 660 nm, 670 nm, 680 nm, 690 nm, 700 nm, 720 nm, 740 nm, 760 nm, 780 nm or 800 nm, or a range defined by any two of the preceding values. In some further embodiments, the second thickness of the imprint layer sufficiently blocks passage of a light having a wavelength between about 225 nm and about 375 nm, or between about 250 nm to about 350 nm. In some embodiments, the difference between the first thickness and the second thickness of the imprint layer is from about 250 nm to about 750 nm, from about 300 nm to about 700 nm, from about 350 nm to about 650 nm, from about 400 nm to about 600 nm, or from about 450 nm to about 550 nm. In some embodiments, the difference between the first thickness and the second thickness of the imprint layer is about 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610nm, 620 nm, 630 nm, 640 nm, 650 nm, 660 nm, 670 nm, 680 nm, 690 nm, 700 nm, 710 nm, 720 nm, 730 nm, 740 nm, or 750 nm, or a range defined by any two of the preceding values. In some other embodiments, the difference between the difference between the first thickness and the second thickness of the imprint layer is at least about 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, or 600 nm, although in some instances other values or ranges may be used.

### Blocking Light Transmission by Reflection

In some other embodiments, the imprint layer may be capable of blocking light by reflection. In such embodiments, the imprint layer may be capable of blocking light to the photoresist where the imprint layer meets or exceeds a certain threshold thickness. For example, the imprint layer may have a series of alternating high refractive index layers (“high RI layers”) and low refractive index layers (“low RI layers”). The refractive index (RI) of the high RI layer is greater than the RI of the low RI layer. Together, this series of high RI layers and low RI layers may act as a dielectric reflector (i.e. a dielectric mirror and/or Bragg reflector). The RI of the high RI layers is about 1.5, about 1.6, about 1.7, about 1.8, about 1.9, about 2.0, about 2.1, about 2.2, about 2.3, about 2.4, about 2.5, about 2.6, about 2.7, about 2.8, about 2.9, about 3, or in a range defined by any two of the preceding values. In some embodiments, the RI of the high RI layer is about 1.5 to about 3, about 1.75 to about 2.75, about 2 to about 2.5, or about 2 to about 2.25. In one embodiment, the RI of the high RI layer is about 2.15. The RI of the low RI layers is about 1.0, about 1.1, about 1.2, about 1.3, about 1.4, about 1.5, about 1.6, about 1.7, about 1.8, about 1.9, about 2.0, about 2.1, about 2.2, about 2.3, about 2.4, about 2.5, or in a range defined by any two of the preceding values. In some embodiments, the RI of the low RI layer is about 1 to about 2.5, about 1.25 to about 2, about 1.25 to about 1.75, or about 1.4 to about 1.6. In one embodiment, the RI of the low RI layers is about 1.5.

In some embodiments, the optical thickness of each of the high RI layers and low RI layers may be approximately equal to a quarter (¼) of the wavelength in a vacuum of light to be blocked. This relationship can be described by Equation 6:

$$6. d = \frac{{λ}_{tar}}{4 n}$$

where d is the thickness of the layer, λₜₐᵣ is the wavelength of the target light, and n is the RI of the material. As an illustrative example, the light to be blocked may have a wavelength of 325 nm. For a high RI layer including Si₃N₄, which may have a RI of 2.15, the layer thickness may be about 38 nm. For a low RI layer including SiO₂, which may have a RI of 1.5, the layer thickness may be about 55 nm. Such optical thicknesses may cause destructive interference light reflected at interfaces between high RI layers and low RI layers.

At each interface between a high RI layer and a low RI layer, some light I_{ref} is reflected back, away from the imprint layer, and some light Iₜᵣₐₙ is transmitted through the interface. A number of alternating high RI layers and low RI layers can be chosen for the deep portion such that, for a given light dosage Iᵢₙₚᵤₜ, at least a light dosage I₁₀₀ sufficient to fully crosslink the photoresist is transmitted to the deep portion of the well, thereby crosslinking the photoresist to in the deep portion. A number alternating high RI layers and low RI layers can be chosen for the shallow portion such that, for a given light dosage Iᵢₙₚᵤₜ, no more than a light dosage I₀, the maximum light dosage at which the photoresist is still completely dissolved, is transmitted to the shallow portion of the well, thereby preventing photoresist from crosslinking in the shallow portion. Transmittivity and reflectance of light within a dielectric reflector is discussed in detail by Sophocles J. Orfanidis, ELECTROMAGNETIC WAVES AND ANTENNAS, 193 (2016) (ebook) (see, e.g., equations 6.3.1-6.3.3), incorporated herein by reference. Generally, the number of alternating layers in the deep portion will be smaller than the number of alternating layers within the shallow portion. Iᵢₙₚᵤₜ can be tuned by altering an intensity of the light source or a duration of exposure. For example, increasing the intensity of the light source may increase Iᵢₙₚᵤₜ while decreasing the intensity of the light source may decrease Iᵢₙₚᵤₜ. As an example, increasing the duration of exposure may increase Iᵢₙₚᵤₜ decreasing the duration of exposure may decrease Iᵢₙₚᵤₜ.

As an illustrative example, the light to be blocked may have a wavelength of 325 nm. For a low RI imprint layer with a RI of 1.4, the optical thickness of each low RI is 325/(1.4*4)=58 nm. For a high RI imprint layer with a RI of 1.7, the optical thickness of each high refractive layer is 325/(1.7*4)=48. When depositing 13 layers of alternating high and low RI imprint layers (i.e., six low RI layers and seven high RI layers), the total thickness of the imprint layer is 6*58+7*48=684 nm. As another example, the light to be blocked may have a wavelength of 250 nm. For a low RI imprint layer with a RI of 1.4, the optical thickness of each low RI is 250/(1.4*4)=44 nm. For a high RI imprint layer with a RI of 1.7, the optical thickness of each high refractive layer is 250/(1.7*4)=37 nm. When depositing 13 layers of alternating high and low RI imprint layers (i.e., six low RI layers and seven high RI layers), the total thickness of the imprint layer is 6*44+7*37=523 nm.

### Photoresist

In one aspect, the present disclosure provides materials for inclusion in a photoresist. In some embodiments, the photoresist is a negative photoresist. In some examples, photoresist material may include NR9-150 (Futurrex, Inc.) and/or NR9-1500 (Futurrex, Inc.), both of which are negative resists. For example, NR9-1500 is a negative lift-off resist optimized for 365 nm wavelength exposure and effective for brand-band exposure.

### Etch-Free Manufacturing Methods

In one aspect, the present disclosure provides methods for preparing a surface of a substrate (e.g., a flow cell) that avoid an etch step. It may be advantageous to eliminate an etch step from a flow cell processing workflow to avoid the additional time, effort, and quality control that such a step typically involves. The etch-free process described herein can create a patterned substrate with two or more functionalized molecules having orthogonal chemical functionalities suitable for SPEAR applications. For example, a first functional molecule and a second functional molecule may both be situated within a nanowell. Because the first functional molecule and the second functional molecule have orthogonal chemical functionalities, the first functional molecule may bind with a first oligonucleotide while the second functional molecule may bind with a second oligonucleotide. This selective reactivity may allow DNA clustering located exclusively at the pre-defined locations—namely, at the first functional molecule. The simplified surface functionalization process may significantly reduce cost, benefiting for flow cell manufacturing.

In an aspect, the present disclosure provides a method for patterning a surface of a substrate. The process may comprise:
introducing a photoresist to a substrate, the substrate comprising an imprint layer positioned over a base support, the imprint layer comprising a plurality of multi-level depressions, each depression comprising a deep portion having a first surface and a shallow portion having a second surface, where distance between the first surface and the base support corresponds to a first thickness of the imprint layer, the distance between the second surface and the base support corresponds to a second thickness of the imprint layer, and the second thickness is greater than the first thickness, and wherein the photoresist resides within at least a portion of the multi-level depressions;
exposing the substrate to light from a backside of the base support opposite to the imprint layer, the first thickness of the imprint layer configured to allow passage of the light to cure at least a portion of the photoresist resided within the deep portion of the multi-level depressions, and the second thickness of the imprint layer configured to sufficiently block passage of the light such that the photoresist resided within the shallow portion of the multi-level depressions remain uncured; and
removing the uncured photoresist from the substrate to expose the second surface of the multi-level depressions.

In some embodiments of the method described herein, the photoresist is a negative photoresist, including any embodiments of the photoresist described in connection with the patterned substrate. In some embodiments, exposing the substrate to light creates a crosslinked photoresist within the deep portion of the plurality of multi-level depressions. In such embodiments, exposing the substrate to light generates a crosslinked photoresist positioned over the first surface of the deep portion of the multi-level depression. In some embodiments of the method described herein, the photoresist is not cured over the second thickness of the imprint layer and is subsequently removed (e.g., by a developer) from the substrate to expose the shallow portion of the multi-level depressions, or expose the second surface of the multi-level depressions.

In embodiments of the method described herein where the crosslinked photoresist is generated, the process may comprise:
depositing a first functionalized molecule over the imprint layer to cover both the cross-linked photoresist and at least a portion of the second surface of the multi-level depressions;
removing the crosslinked photoresist in the deep portion of the multi-level depressions to expose the first surface of the multi-level depressions; and
depositing a second functionalized molecule over at least a portion of the first surface of the multi-level depressions. In some embodiments, the first and the second functionalized molecules are functionalized hydrogel or polymer described herein in connection with the patterned substrate.

In some embodiments of the method described herein, the method may further comprises imprinting the imprint layer with a template/stamp to generate the plurality of multi-level depressions.

In some embodiments of the method described herein, the light transmission is blocked or substantially blocked by the second thickness of the imprint layer through absorption, as described in details in connection with the patterned substrate. In some such embodiments, the first thickness of the imprint layer is from about 0 nm to about 200 nm. For example, the first thickness may be about 5 nm, 10 nm, 15 nm 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 110 nm, 120 nm, 130 nm, 140 nm, 150 nm, 160 nm, 170 nm, 180 nm, 190 nm or 200 nm, or a range defined by any two of the preceding values. In some further embodiments, the first thickness of the imprint layer allows sufficient passage of a light having a wavelength between about 225 nm and about 375 nm, or between about 250 nm to about 350 nm. In some embodiments, the percentage transmittal of the light through the first thickness of the imprint layer is at least 70%, 75%, 80%, 85%, 90%, 95% or 99%. In some embodiments, the second thickness of the imprint layer is from about 350 nm to about 800 nm. For example, the second thickness may be about 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 720 nm, 740 nm, 760 nm, 780 nm or 800 nm, or a range defined by any two of the preceding values. In some further embodiments, the second thickness of the imprint layer sufficiently blocks passage of a light having a wavelength between about 225 nm and about 375 nm, or between about 250 nm to about 350 nm. In some embodiments, the difference between the first thickness and the second thickness of the imprint layer is from about 250 nm to about 750 nm, from about 300 nm to about 700 nm, from about 350 nm to about 650 nm, from about 400 nm to about 600 nm, or from about 450 nm to about 550 nm. In some embodiments, the difference between the first thickness and the second thickness of the imprint layer is about 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, or 750 nm, or a range defined by any two of the preceding values. In some other embodiments, the difference between the difference between the first thickness and the second thickness of the imprint layer is at least about 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, or 600 nm, although in some instances other values or ranges may be used.

In some embodiments of the method described herein, the imprint layer comprises one or more photoacid generators (PAGs), one or more photo initiators (PIs), or combinations thereof. In such embodiments, the one or more PAG(s) may be selected from the group consisting of bis(4-methylphenyl)iodonium hexafluorophosphate, tris(4-((4-acetylphenyl)thio)phenyl)-sulfonium tetrakis(perfluorophenyl)borate, 2-isopropylthioxanthone, cationic epoxy silicone (for example, TEGO® Photo Compound 1467), 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PAG(s), or a range defined by any two of the preceding values. In some embodiments, the imprint layer includes from about 0.1% to about 20% PAG(s) by weight, about 0.5% to about 15% PAG(s) by weight, about 1% to about 10% PAG(s) by weight, about 2% to about 9% PAG(s) by weight, about 3% to about 8% PAG(s) by weight, about 4% to about 7% PAG(s) by weight, or about 4% to about 6% PAG(s) by weight. In some embodiments, the imprint layer includes at least 0.1%, 0.5%, 1%, 2%, 3%, 4%, 5%, 6%, 7%, 8%, 9% or 10% of PAG(s) by weight, though in some instances other values or ranges may be used. The one or more PI(s) may be selected from the group including diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphine oxide, ethyl(2,4,6-trimethylbenzoyl) phenylphosphinate, 4,4′-bis(diethylamino)benzophenone, benzoin ethyl ether, 2,2-diethoxyacetophenone, and 4′-phenoxyacetophenone. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PI(s), or a range defined by any two of the preceding values. In some embodiments, the imprint layer includes from about 0.1% to about 20% PI(s) by weight, about 0.5% to about 15% PI(s) by weight, about 1% to about 10% PI(s) by weight, about 2% to about 9% PI(s) by weight, about 3% to about 8% PI(s) by weight, about 4% to about 7% PI(s) by weight, or about 4% to about 6% PI(s) by weight. In some embodiments, the imprint layer includes at least 0.1%, 0.5%, 1%, 2%, 3%, 4%, 5%, 6%, 7%, 8%, 9% or 10% of PI(s) by weight, though in some instances other values or ranges may be used.

In some embodiments of the method described herein, the imprint layer further comprises one or more additives selected from the group consisting of ZnO particles, ZrO₂ particles, TiO₂ particles, epoxy compounds of ZnO, ZrO₂, or TiO₂, black hole quenchers™, carbon particles, avobenzone, bisoctrizole, bismotriznol, meradimate, dioxybenzone, oxybenzone, drometrizole, 4-methacryloxy-2-hydroxybenzophenone, 2,2-dihydroxy-4-methoxybenzophenone, drometrizole trisiloxane, methyl-2-cyan-3-(4-hydroxyphenyl)acrylate, (E)-ethyl 2-(3-ethoxy-4-hydroxybenzylidene)-3-oxobutanoate, ethyl-2-cyano-3-(4-hydroxy-3-methoxy phenyl)acrylate, and dimethyl 2-(4-hydroxybenzylidene)malonate, and combinations thereof.

In some embodiments of the method described herein, the imprint layer comprises at one or more leveling agents (LAs). In some embodiments, the leveling agent is used to enhance the thickness uniformity of the imprint layer. In further embodiments, the leveling agent includes a polyacrylate or a polyacrylate co-polymer. In yet further embodiments, the leveling agent is selected from the group consisting of BYK-350 (BYK-Chemie GmbH), BYK-394 (BYK-Chemic GmbH), BYK-354 (BYK-Chemie GmbH), BYK-392 (BYK-Chemie GmbH), BYK-352 (BYK-Chemic GmbH), BYK-356 (BYK-Chemie GmbH), and BYK-359 (BYK-Chemic GmbH). In some embodiments, the imprint layer comprises about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, or 10% leveling agent(s) by weight, or a range defined by any two of the preceding values. In some embodiments, the imprint layer includes from about 0.1% to about 10% LA(s) by weight, about 0.5% to about 8% LA(s) by weight, about 1% to about 6% LA(s) by weight, or about 1.5% to about 4% LA(s) by weight. In some embodiments, the imprint layer includes at least 0.1%, 0.2%, 0.4%, 0.6%, 0.8%, 1%, 1.2%, 1.4%, 1.6%, 1.8%, 2%, 3.0%, 4.0% 5%, 6%, 7%, 8%, 9% or 10% of LA(s) by weight, though in some instances other values or ranges may be used.

In some other embodiments of the method described herein, the light transmission is blocked or substantially blocked by the second thickness of the imprint layer through reflection, as described in details in connection with the patterned substrate. In some such embodiments, the imprint layer comprises a stack of alternating layers of a first material and a second material, the first material having a high RI and the second material having a low RI. In some such embodiments, the second thickness of the imprint layer comprises at least seven layers of the stack. In some such embodiments, the second thickness of the imprint layer is configured to block light by reflection. In some such embodiments, the first material comprises Si₃N₄ and the second material comprises SiO₂. In some such embodiments where the first material comprises first material comprises Si₃N₄ and the second material comprises SiO₂, each layer of the stack of the first material is 38 nm thick and each layer of the second material is 55 nm thick. In other embodiments, the first material and the second material may include POSS or nanoimprint lithography (NIL) resin materials with different RIs (e.g., different opacities).

In some embodiments of the method described herein, at least a portion of the plurality of multi-level depressions are nanowells each comprising a deep portion and a shallow portion.

In some embodiments of the method described herein, the method does not include an etching step.

Further embodiments of the present disclosure also include patterned substrate prepared by the etch-free method described herein.

### EXAMPLES

Some aspects of the embodiments discussed above are disclosed in further detail in the following examples, which are not in any way intended to limit the scope of the present disclosure. Those in the art will appreciate that many other embodiments also fall within the scope of the compositions, kits and methods of the present application, as is described herein above and in the claims.

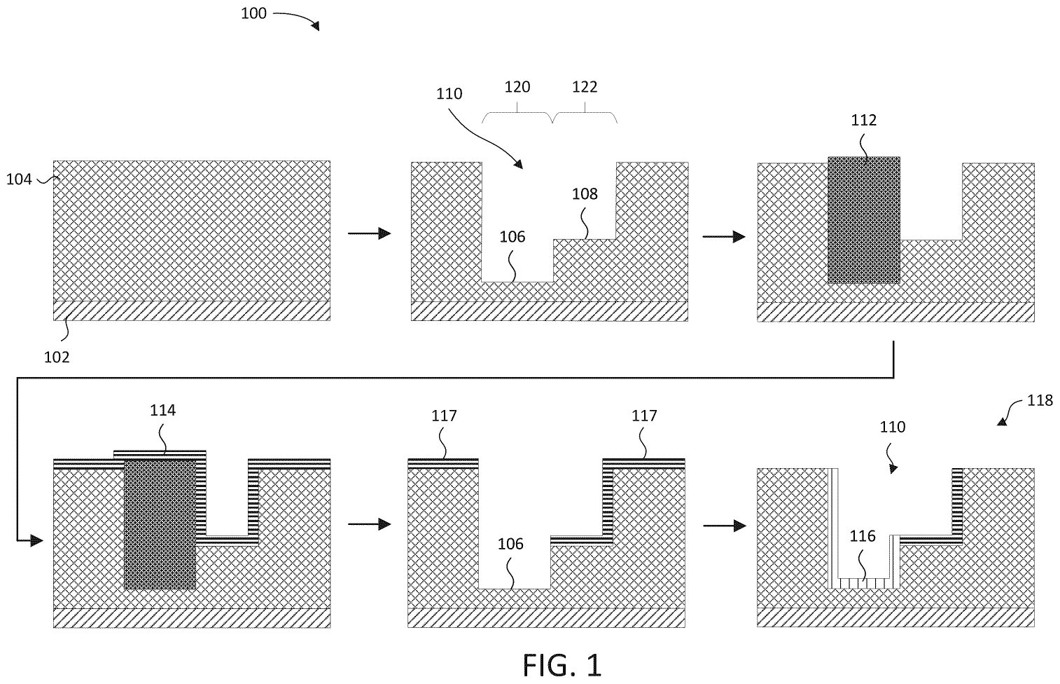

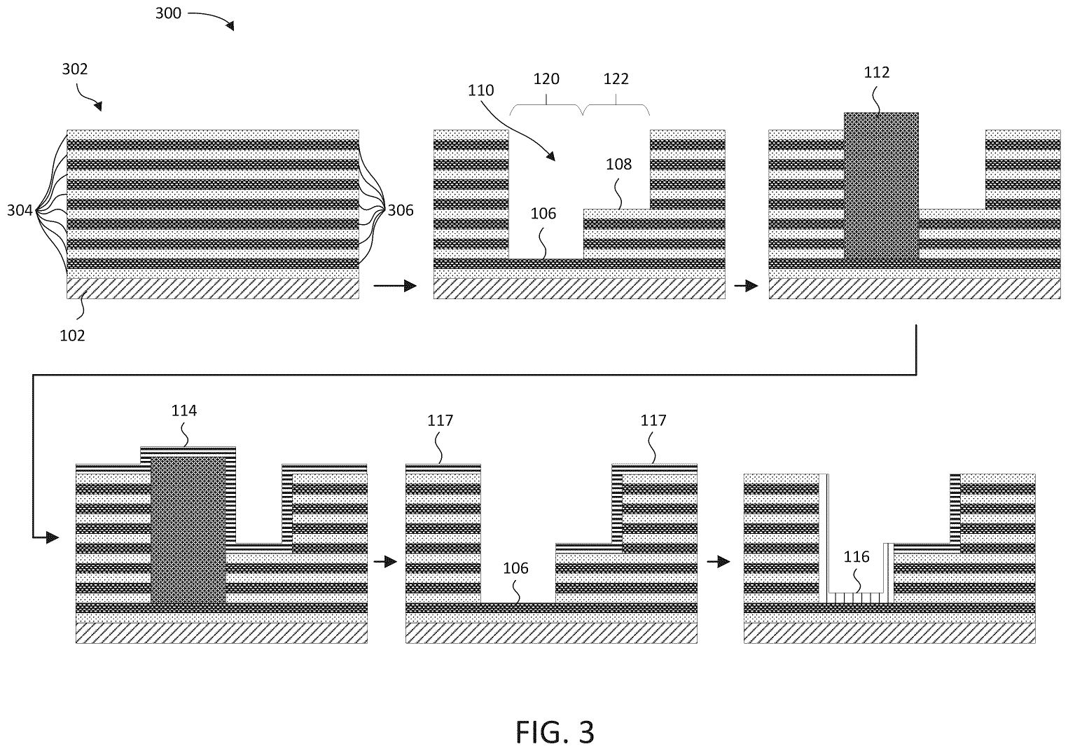

In some examples, as illustrated in FIG. 1 and FIG. 3, etch-free workflows may be used to create a substrate (e.g., a flow cell) including functionalized nanowells.

### Example 1

### Etch-Free Process for Preparing a Substrate Surface

FIG. 1 illustrates an exemplary etch-free process 100 for creating a SPEAR substrate (e.g., flow cell) surface 118. An imprint layer 104 may be laid over a base support 102.

The imprint layer 104 may be contacted with a working stamp. The working stamp may imprint a plurality of multi-level depressions 110 (only one depression 110 is shown in FIG. 1) into the imprint layer 104. In some embodiments, the depression 110 may be a well. In some embodiments, the depression 110 may be a nanowell. The depression 110 includes a deep portion 120 having a first surface 106 and a shallow portion 122 having a second surface 108. The imprint layer 104 may undergo crosslinking such that the imprint layer 104 holds the shape of the depression 110 imprinted by the working stamp. The first surface 106 of the depression 110 may be positioned closer to the base support 102 than the second surface 108 of the depression 110.

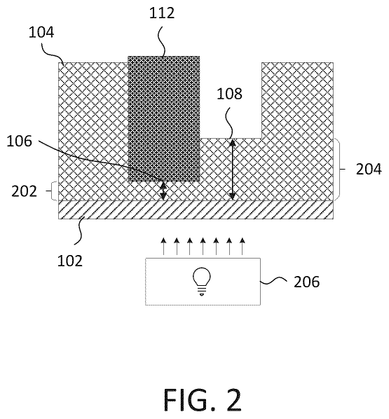

A photoresist may be laid over the imprint layer 104. As depicted in FIG. 2, a light source 206 may transmit light through the base support 102 to the imprint layer 104. The light source 206 may be positioned at a backside of the base support 102 (i.e., on a side of the base layer 102 opposite the imprint layer 104). A first thickness 202 of the imprint layer 104 may correspond to the distance between an upper surface of the base support 102 and the first surface 106. A second thickness 204 of the imprint layer 104 may correspond to the distance between an upper surface of the base support 102 and the second surface 108. The first thickness 202 of imprint layer 104 may be relatively permissive to passage of light emitted from light source 206. For example, the first thickness 202 may transmit sufficient light from light source 206 such that the photoresist above first surface 106 can be cured after light exposure. The second thickness 204 may be relatively impermissive to passage of light emitted from light source 206. For example, the second thickness 204 may block light from light source 206 such that no, substantially no, and/or minimal photoresist is cured over the second surface 108 after the light exposure duration. The second thickness 204 may block light from reaching the photoresist by absorbing light.

Again with reference to FIG. 1, the photoresist may be cured to form a column of crosslinked photoresist 112 above first surface 106 after sufficient exposure to light, though the photoresist may not have cured above other surfaces of the imprint layer 104, such as above second surface 108. Photoresist that remains uncured may be removed from the surface of the substrate, leaving only crosslinked photoresist 112 in the depression 110. A first functionalized molecule 114 may be layered over the top surface of the substrate, covering one or more exposed surfaces of the imprint layer 104 (including second surface 108), the crosslinked photoresist 112, and the interstitial regions 117. The first functionalized molecule 114 may be any suitable molecule with the present disclosure, for example a functionalized hydrogel. The crosslinked photoresist 112 may be removed to re-expose surfaces of the imprint layer 104, including re-exposing the first surface 106. At least a portion of the first functionalized molecule 114, for example the portion of the first functionalized molecule 114 layered over the crosslinked photoresist 112, are also removed. A second functionalized molecule 116 may be deposited over the re-exposed surfaces of the imprint layer 104. Specifically, the second functionalized molecule 116 may be layered over the first surface 106. The second functionalized molecule 116 may be any suitable hydrogel, including a functionalized hydrogel in accordance with the present disclosure. A polish step may remove the first functionalized molecule 114 and/or second functional molecule 116 from surfaces of the imprint layer 104 exterior to the depression 110, for example from the interstitial regions 117. The first functionalized molecule 114 and second functionalized molecule 116 may remain within the depression 110 after the polish step.

### Example 2

### Etch-Free Process for Preparing a Substrate Surface

FIG. 3 illustrates an exemplary etch-free process 300 for creating a SPEAR substrate (e.g., flow cell) surface. A stacked imprint layer 302 may be layered over the base support 102. The stacked imprint layer 302 may include one or more high RI layers 304 and one or more low RI layers 306. The high RI layers 304 and low RI layers 306 may be sequentially deposited on the base support, for example by spin coating. The high RI layers 304 and low RI layers 306 of the stacked imprint layer 302 may alternate as shown in FIG. 3. The high RI layers 304 need not be the same thickness as the low RI layers 306.

The stacked imprint layer 302 may be contacted with a working stamp. The working stamp may imprint a depression 110 into the stacked imprint layer 302. In some embodiments, the depression 110 may be a nanowell. The depression 110 includes deep portion 120 having a first surface 106 and shallow portion 122 having a second surface 108. The stacked imprint layer 302 may undergo crosslinking such that the stacked imprint layer 302 holds the shape of the depression 110 imprinted by the working stamp. The first surface 106 of the depression 110 may be positioned closer to the base support 102 than the second surface 108 of the depression 110.

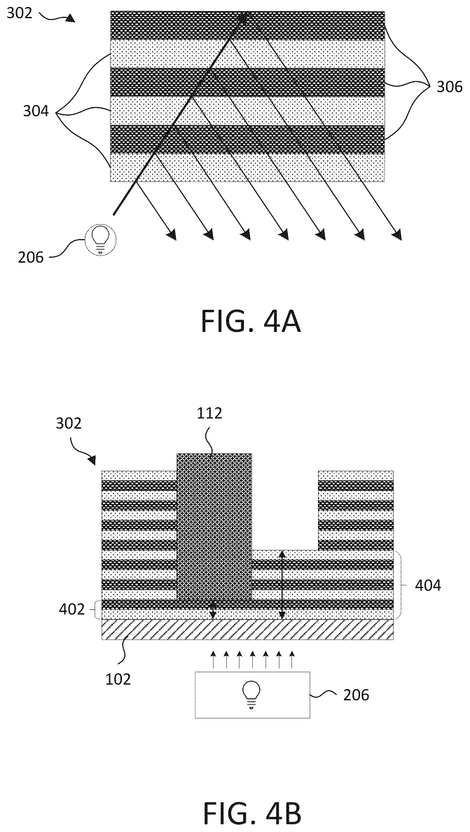

A photoresist may be laid over the imprint layer 104. As depicted in FIG. 4A, the stacked imprint layer 302 may act as a dielectric reflector. Light may be transmitted into the stacked imprint layer 302. The light source 206 may be positioned at a backside of the base support 102 (i.e., on a side of the base support 102 opposite the stacked imprint layer 302). At interfaces between each high RI layer 304 and low RI layer 306, some fraction of the light may be reflected back. Now with reference to FIG. 4B, a light source 206 may transmit light through the base support 102 to the stacked imprint layer 302. A first thickness 402 of the stacked imprint layer 302 may correspond to the distance between an upper surface of the base support 102 and the first surface 106. The first thickness 402 may correspond to a first number of high RI layers 304 and a first number of low RI layers 306. For example, the first thickness 402 may correspond to one high RI layer 304 and one low RI layer 306. A second thickness 404 of the stacked imprint layer 302 may correspond to the distance between an upper surface of the base support 102 and the second surface 108. The second thickness 404 of the stacked imprint layer 302 may correspond to a second number of high RI layers 304 and a second number of low RI layers 306. For example, the second thickness 404 may correspond to four high RI layers 304 and three low RI layers 306. The first thickness 402 of imprint layer 302 may be relatively permissive to passage of light emitted from light source 206. For example, the first thickness 402 may transmit sufficient light from light source 206 such that the photoresist above first surface 106 can be cured after light exposure. The second thickness 404 may be sufficiently impermissive to passage of light emitted from light source 206. For example, the second thickness 204 may block light from light source 206 such that the photoresist does not receive a sufficient light dosage to cure the photoresist. The second thickness 204 may block light from reaching the photoresist by reflecting the light at the interfaces of the high RI layers 304 and low RI layers 306.

Again with reference to FIG. 3, the photoresist may be cured to form a column of crosslinked photoresist 112 above first surface 106 with sufficient exposure to light, though the photoresist may not have cured above other surfaces of the stacked imprint layer 302, such as above second surface 108. Photoresist that remains uncured may be removed from the surface of the substrate, leaving only crosslinked photoresist 112 in the depression 110. A first functionalized molecule 114 may be layered over the top surface of the substrate, covering one or more exposed surfaces of the stacked imprint layer 302, the crosslinked photoresist 112, and the interstitial regions 117. The first functionalized molecule 114 may be any suitable hydrogel, including a functionalized hydrogel in accordance with the present disclosure. The crosslinked photoresist 112 may be removed to re-expose surfaces of the imprint layer 104, including re-exposing the first surface 106. At least a portion of the first functionalized molecule 114, for example the portion of the first functionalized molecule 114 layered over the crosslinked photoresist 112, are removed. A second functionalized molecule 116 may be layered over the re-exposed surfaces of the imprint layer 104. Specifically, the second functionalized molecule 116 may be deposited over the first surface 106. The second functionalized molecule 116 may be any suitable hydrogel, including a functionalized hydrogel in accordance with the present disclosure. A polish step may remove the first functionalized molecule 114 and/or second functional molecule 116 from surfaces of the stacked imprint layer 302 exterior to the depression 110, for example from the interstitial regions 117. The first functionalized molecule 114 and second functionalized molecule 116 may remain within the depression 110 after the polish step.

### Example 3

### Transmittivity of Imprint Layer Materials

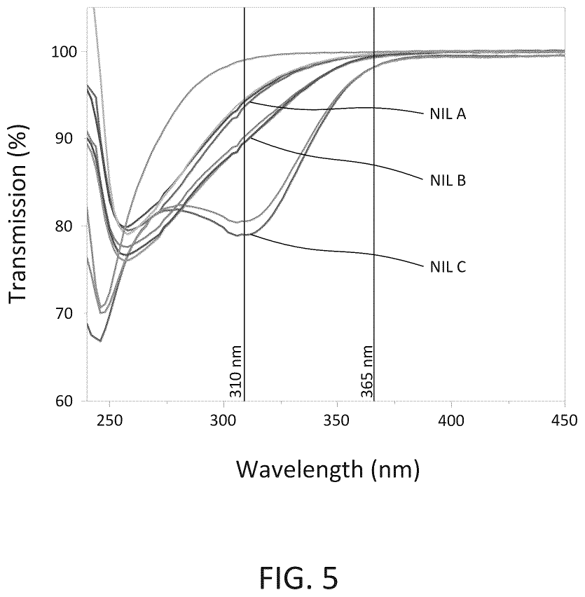

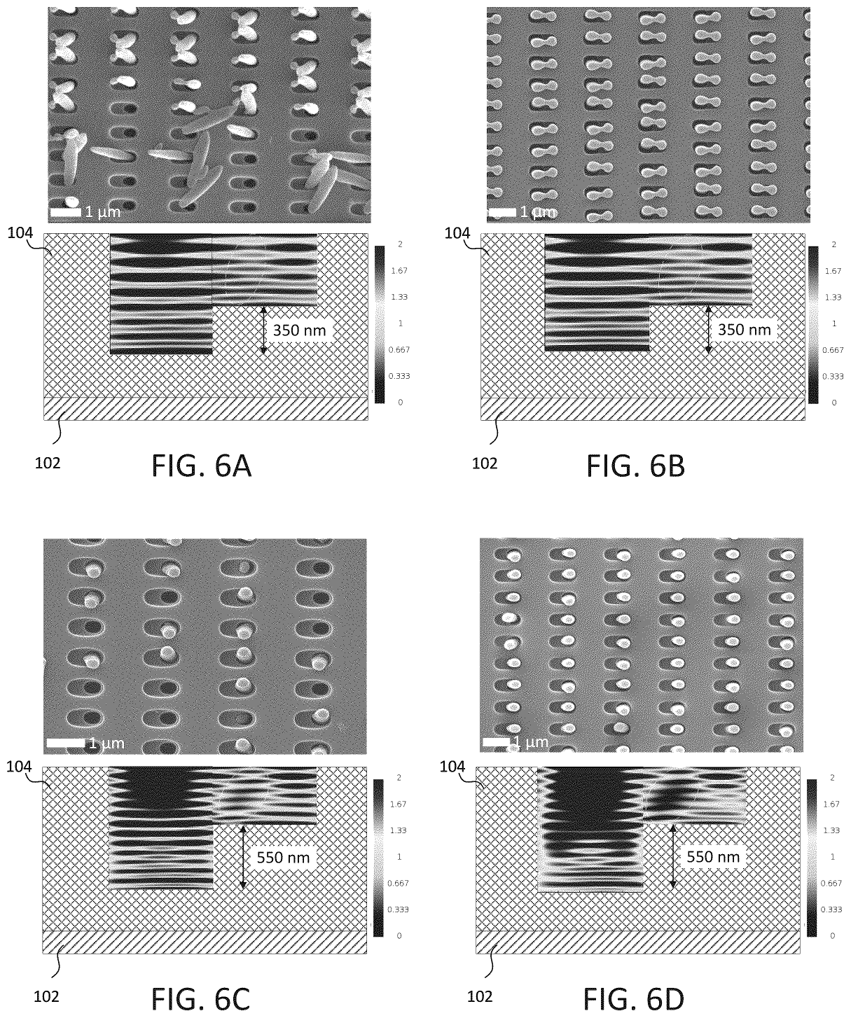

Several NIL resins were tested for their capacity to transmit and/or absorb light having wavelength of approximately 240 nm to 450 nm. FIG. 5 is a plot of the transmissivity of the tested NIL resins over these wavelengths. Each of the tested resins had a different chemistry. Three particular resins, NIL A, NIL B, and NIL C, are identified in FIG. 5 because of their relevance to FIG. 6. The transmission of all the tested NIL resins approached 100% (i.e., the resins were optically transparent) at about 365 nm and above. At about 310 nm, the transmission of NIL C was about 80%, while the transmission of NIL B was about 90% and the transmission of NIL A was about 93%. The difference in transmission profiles may make certain NIL resins more desirable for inclusion in the imprint layer of particular substrate designs and/or use with particular photoresist chemistries.

### Example 4

### Exemplary Etch-Free Processes

As illustrated in FIGS. 6A-6D, four different processes in accordance with the present disclosure were tested. Each of the substrates presented in FIGS. 6A-6D received the same dose of light. Each of FIGS. 6A-6D show a scanning electron microscope (SEM) image (top) and a plot of light intensity within a multi-level depression (bottom).

FIG. 6A shows a SEM image and light intensity plot for a first example process. This process included NIL formulation A in the imprint layer 104 and transmitted 365 nm-450 nm light from below the base support 102 to the substrate. Formulation A contains 1% PI, 2.5% PAG, and 1.6% leveling agent. The thickness difference between the deep portion and the shallow portion of the depression was 350 nm. The SEM image shows crosslinked photoresist within the shallow portion of some of the depressions, while some of the depressions do not include crosslinked photoresist within the deep portion of the depressions.

FIG. 6B shows a SEM image light intensity plot for a second example process. This process included NIL formulation B in the imprint layer 104 and transmitted 310 nm light from below the base support 102 to the substrate. Formulation B contains 1% PI, 4% PAG, and 0.95% leveling agent. The thickness difference between the deep portion and the shallow portion of the depression was 350 nm. The SEM image shows crosslinked photoresist within the shallow portions of all depressions.

FIG. 6C shows a SEM image and a light intensity plot for a third example process. This process included NIL formulation B in the imprint layer 104 and transmitted 310 nm light from below the base support 102 to the substrate. The thickness difference between the deep portion and the shallow portion of the depression was 550 nm. The SEM image shows that there is no crosslinked photoresist within the shallow portion of the depressions. However, the SEM image also shows that some of the depressions do not include crosslinked photoresist within the deep portion.

FIG. 6D shows a SEM image and a light intensity plot for a third example process. This process included NIL formulation C in the imprint layer 104 and transmitted 310 nm light from below the base support 102 to the substrate. Formulation C contains 1% PI, 5% PAG, and 1.6% leveling agent. The SEM image shows that all depressions include crosslinked photoresist within the deep portion, and no crosslinked photoresist within the shallow portion. The thickness difference between the deep portion and the shallow portion of the depression was 550 nm. With reference to FIG. 6D, the combination of resin, light wavelength, and thickness of the imprint layer at the shallow portion of the depression resulted in the lowest light intensity within the shallow portion of the depression, as indicated by the circled portion of the light intensity heatmap. Without being bound to a particular theory, it is believed that the relatively low light intensity within the shallow portion, coupled with relatively high light intensity within the deep portion, contributed to consistent photocuring of the photoresist within the deep portion of the depression.

1. A patterned substrate, comprising:
a base support; and
an imprint layer positioned over the base support, the imprint layer comprising a plurality of multi-level depressions, each depression comprising a deep portion having a first surface, and a shallow portion having a second surface, the deep portion and the shallow portion are defined by a step portion, wherein distance between the first surface and the base support corresponds to a first thickness of the imprint layer, the distance between the second surface and the base support corresponds to a second thickness of the imprint layer, and the second thickness is greater than the first thickness;
wherein the first thickness of the imprint layer is configured to allow sufficient passage of light to the deep portion of the depression to crosslink a photoresist, and the second thickness of the imprint layer is configured to sufficiently block passage of light to the shallow portion of the depression to inhibit crosslinking of the photoresist.

2. The patterned substrate of claim 1, wherein a first functionalized molecule covers at least a portion of the first surface, and a second functionalized molecule covers at least a portion of the second surface.

3. The patterned substrate of claim 2, wherein the first functionalized molecule is a functionalized hydrogel or polymer comprising a plurality of first functional groups, the second functionalized molecule is a functionalized hydrogel or polymer comprising a plurality of second functional groups, and wherein the first functional groups are orthogonal to the second functional groups.

4. The patterned substrate of claim 1, wherein the first thickness of the imprint layer is about 0 nm to about 200 nm.

5. The patterned substrate of claim 4, wherein the first thickness of the imprint layer allows sufficient passage of a light having a wavelength between about 225 nm and about 375 nm, or between about 250 nm to about 350 nm.

6. The patterned substrate of claim 5, wherein the percentage transmittal of the light through the first thickness of the imprint layer is at least 85%.

7. The patterned substrate of claim 1, wherein the second thickness of the imprint layer is about 350 nm to about 800 nm.

8. The patterned substrate of claim 7, wherein the second thickness of the imprint layer sufficiently blocks passage of a light having a wavelength between about 225 nm and about 375 nm or between about 250 nm to about 350 nm.

9. The patterned substrate of claim 1, wherein the second thickness of the imprint layer is configured to block light by absorption.

10. The patterned substrate of claim 1, wherein the imprint layer comprises polyhedral oligomeric silsesquioxane (POSS).

11. The patterned substrate of claim 1, wherein the imprint layer comprises one or more photoacid generators (PAG) or photo initiators (PI), or a combination thereof.

12. The patterned substrate of claim 11, wherein the one or more photoacid generators are selected from the group consisting of bis(4-methylphenyl)iodonium hexafluorophosphate, tris(4-((4-acetylphenyl)thio)phenyl)-sulfonium tetrakis(perfluorophenyl)borate, 2-isopropylthioxanthone, TEGO® 1467, 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate, and combination thereof.

13. The patterned substrate of claim 11, wherein the imprint layer comprises at least 1% photo acid generator by weight.

14. The patterned substrate of claim 11, wherein the one or more photo initiators are selected from the group consisting of diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphine oxide, ethyl(2,4,6-trimethylbenzoyl) phenylphosphinate, 4,4′-bis(diethylamino)benzophenone, benzoin ethyl ether, 2,2-diethoxyacetophenone, and 4′-phenoxyacetophenone, and combinations thereof.

15. The patterned substrate of claim 14, wherein the imprint layer comprises at least 1% photo initiator by weight.

16. The patterned substrate of claim 1, wherein the imprint layer further comprises one or more additives selected from the group consisting of ZnO particles, ZrO2 particles, TiO2 particles, epoxy compounds of ZnO, ZrO2, or TiO2, black hole quenchers™, carbon particles, avobenzone, bisoctrizole, bismotriznol, meradimate, dioxybenzone, oxybenzone, drometrizole, 4-methacryloxy-2-hydroxybenzophenone, 2,2-dihydroxy-4-methoxybenzophenone, drometrizole trisiloxane, methyl-2-cyan-3-(4-hydroxyphenyl)acrylate, (E)-ethyl 2-(3-ethoxy-4-hydroxybenzylidene)-3-oxobutanoate, ethyl-2-cyano-3-(4-hydroxy-3-methoxy phenyl)acrylate, and dimethyl 2-(4-hydroxybenzylidene)malonate, and combinations thereof.

17. The patterned substrate of claim 1, wherein the imprint layer further comprises at least one leveling agents (LA).

18. The patterned substrate of claim 17, wherein the leveling agent comprises a polyacrylate or a polyacrylate co-polymer.

19. (canceled)

20. The patterned substrate of claim 1, wherein the second thickness of the imprint layer is configured to block light by reflection.

21. The patterned substrate of claim 20, wherein the imprint layer comprises a stack of alternating layers of a first material and a second material, the first material having a first refractive index and the second material having a second refractive index, the first refractive index higher than the second refractive index.

22. The patterned substrate of claim 21, wherein the second thickness of the imprint layer comprises at least seven alternating layers of the stack.

23. The patterned substrate of claim 21, wherein the first material comprises Si₃N₄ and the second material comprises SiO₂, wherein each layer of the stack of the first material has a thickness of about 38 nm, and each layer of the second material has a thickness of about 55 nm.

24.-26. (canceled)

27. The patterned substrate of claim 1, wherein the base support is transparent.

28. A method for patterning a surface of a substrate, comprising:
introducing a photoresist to a substrate, the substrate comprising an imprint layer positioned over a base support, the imprint layer comprising a plurality of multi-level depressions, each depression comprising a deep portion having a first surface and a shallow portion having a second surface, where distance between the first surface and the base support corresponds to a first thickness of the imprint layer, the distance between the second surface and the base support corresponds to a second thickness of the imprint layer, and the second thickness is greater than the first thickness, and wherein the photoresist resides within at least a portion of the multi-level depressions;
exposing the substrate to light from a backside of the base support opposite to the imprint layer, the first thickness of the imprint layer configured to allow passage of the light to cure at least a portion of the photoresist resided within the deep portion of the multi-level depressions, and the second thickness of the imprint layer configured to sufficiently block passage of the light such that the photoresist resided within the shallow portion of the multi-level depressions remain uncured; and
removing the uncured photoresist from the substrate to expose the second surface of the multi-level depressions.

29.-52. (canceled)
